(19) United States
(12) Patent Application Publication
(10) Pub. No.: US 2026/0086300 A1
(43) Pub. Date: Mar. 26, 2026

(54) SEMICONDUCTOR DEVICE AND FORMING METHOD OF THE SAME

(71) Applicant: Taiwan Semiconductor Manufacturing Company, Ltd., Hsinchu (TW)

(72) Inventors: Ming-Fa Chen, Taichung City (TW); Hao-Tien Cheng, Hsinchu (TW); Chia-Han Tsou, Hsinchu (TW)

(73) Assignee: Taiwan Semiconductor Manufacturing Company, Ltd., Hsinchu (TW)

(21) Appl. No.: 18/893,808

(22) Filed: Sep. 23, 2024

(51) Int. Cl. G02B 6/42; H01L 25/16

(52) U.S. Cl. CPC G02B 6/4214; G02B 6/4239; H10W 90/00

(57) ABSTRACT

A semiconductor device includes a photonic die and a reflector coupler. The photonic die includes an edge coupler. At least a portion of the reflector coupler is disposed outside the photonic die. A light from the edge coupler is reflected by the reflector coupler, or a light is reflected by the reflector coupler and then incident into the edge coupler.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing integrated circuit packages or package assemblies have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1L are schematic cross-sectional views of various stages in a method of forming a semiconductor device according to some embodiments.

FIG. 2 is a schematic cross-sectional view of a semiconductor device according to some embodiments.

FIG. 3A and FIG. 3B are a schematic cross-sectional view of a semiconductor device according to some embodiments.

FIG. 4A and FIG. 4B are a schematic cross-sectional view of a semiconductor device according to some embodiments.

FIG. 5A to FIG. 5E are schematic cross-sectional views of various stages in a method of forming a semiconductor device according to some embodiments.

FIG. 6A to FIG. 6E are schematic cross-sectional views of various stages in a method of forming a semiconductor device according to some embodiments.

FIG. 7 is a schematic cross-sectional view of a semiconductor device according to some embodiments.

FIG. 8 is a schematic cross-sectional view of a semiconductor device according to some embodiments.

FIG. 9A to FIG. 9D are schematic cross-sectional views of various stages in a method of forming a semiconductor device according to some embodiments.

FIG. 10 is a schematic cross-sectional view of a semiconductor device according to some embodiments.

FIG. 11 is a schematic cross-sectional view of a semiconductor device according to some embodiments.

FIG. 12 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in physical contact, and may also include embodiments in which additional features may be formed between the first and second features, such that the first and second features may not be in physical contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

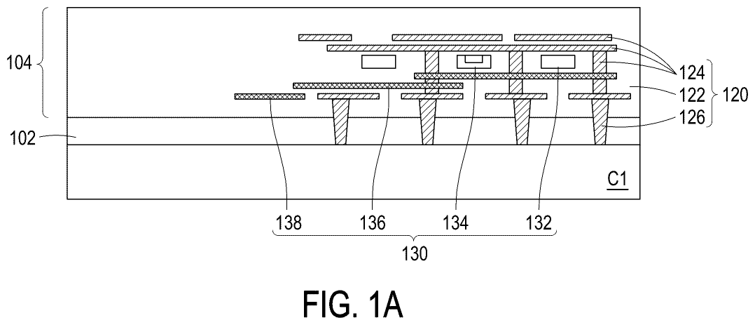

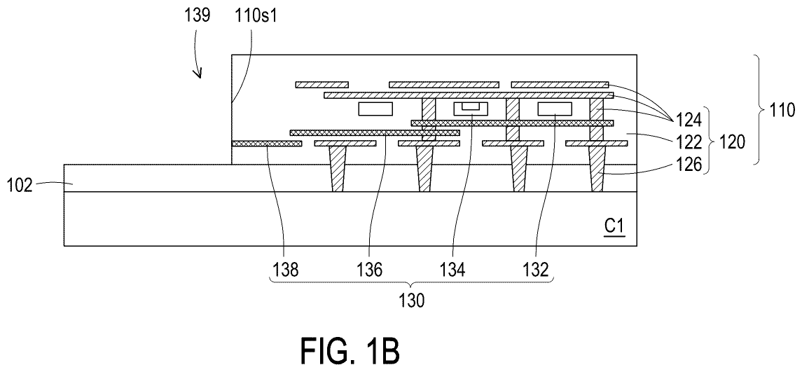

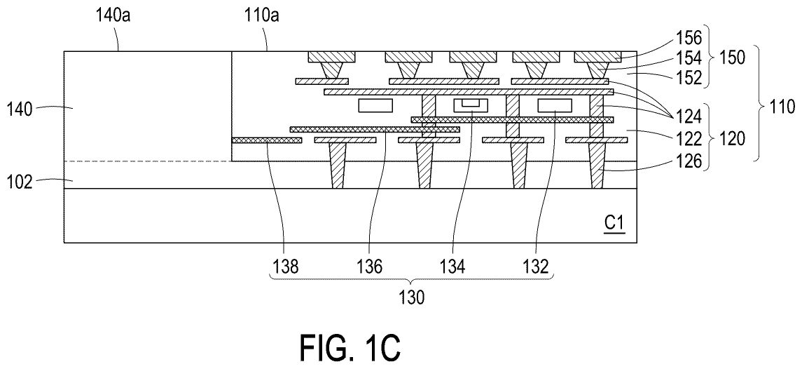

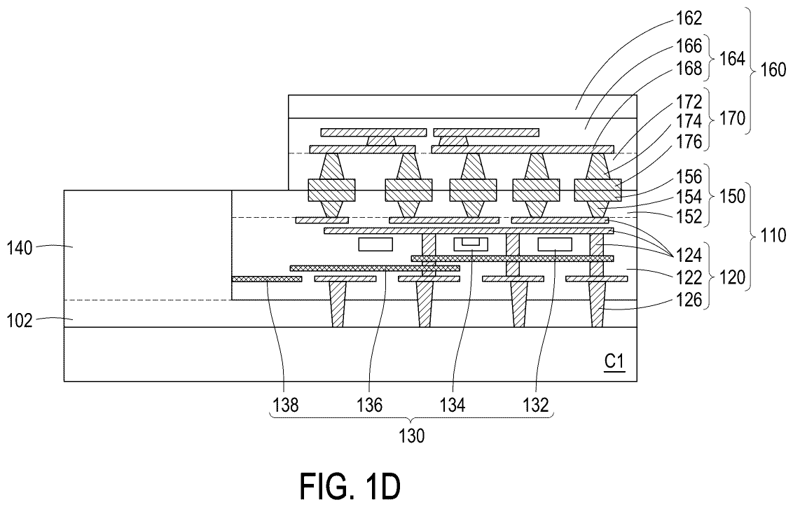

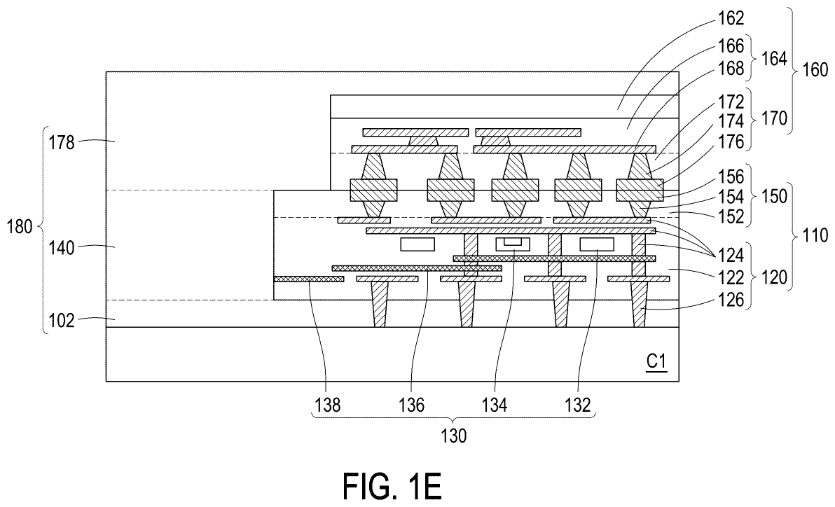

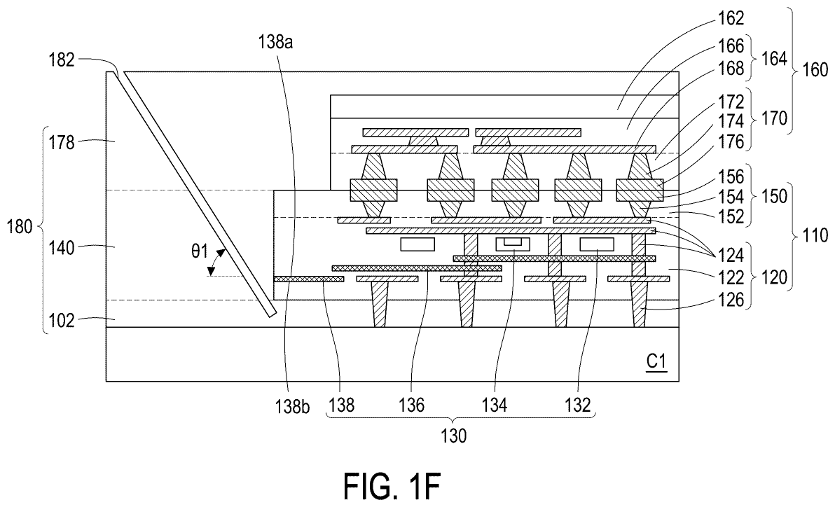

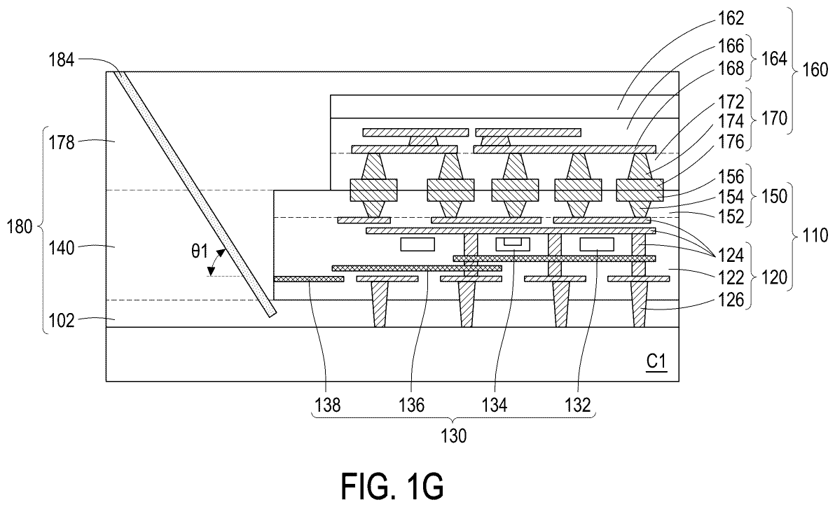

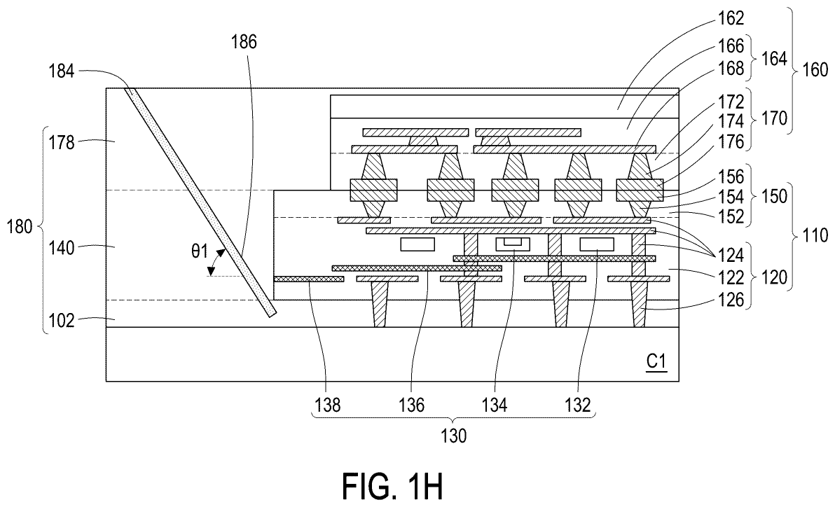

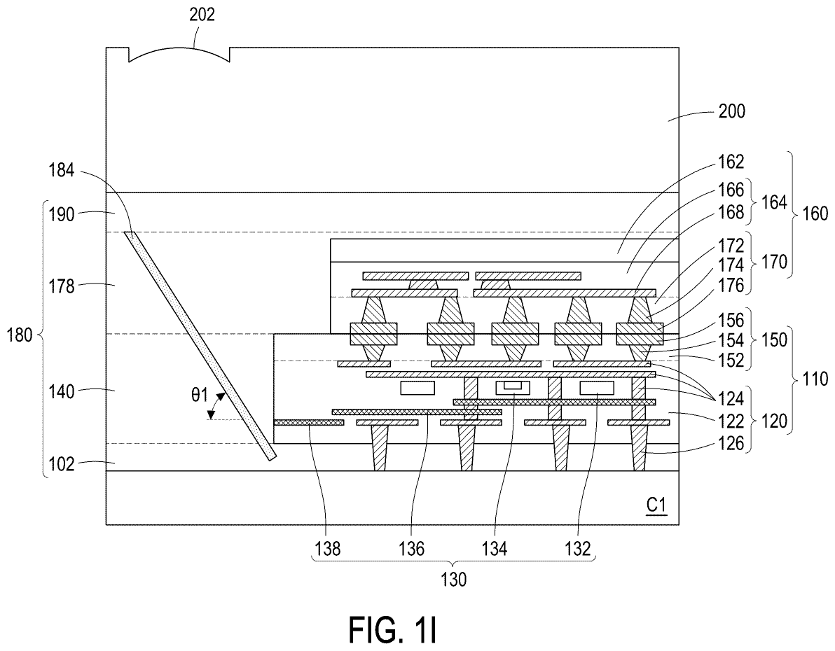

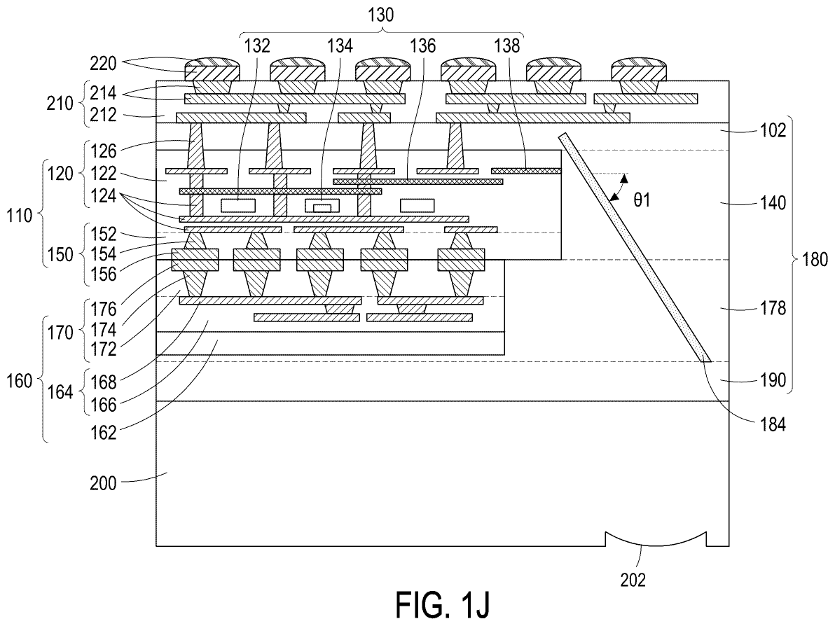

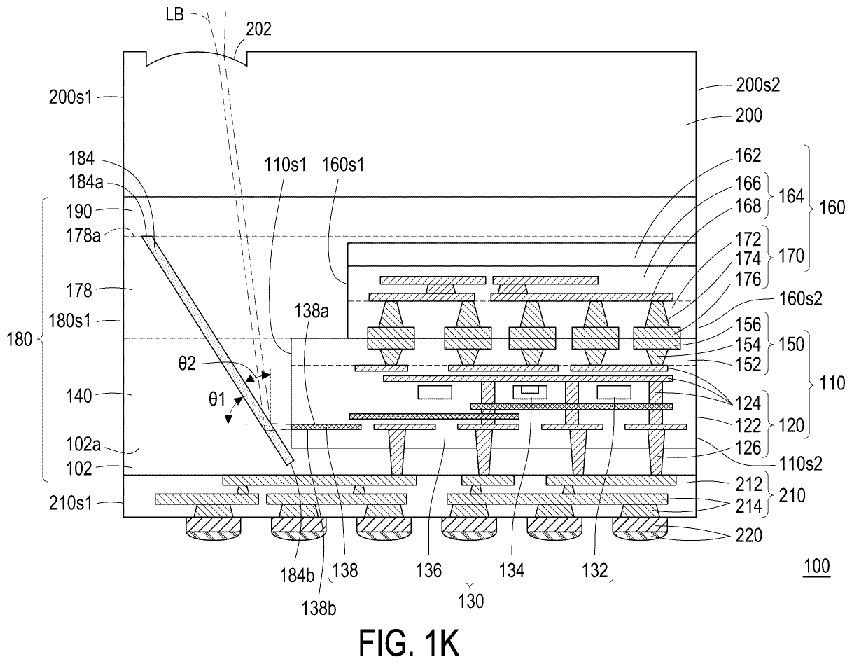

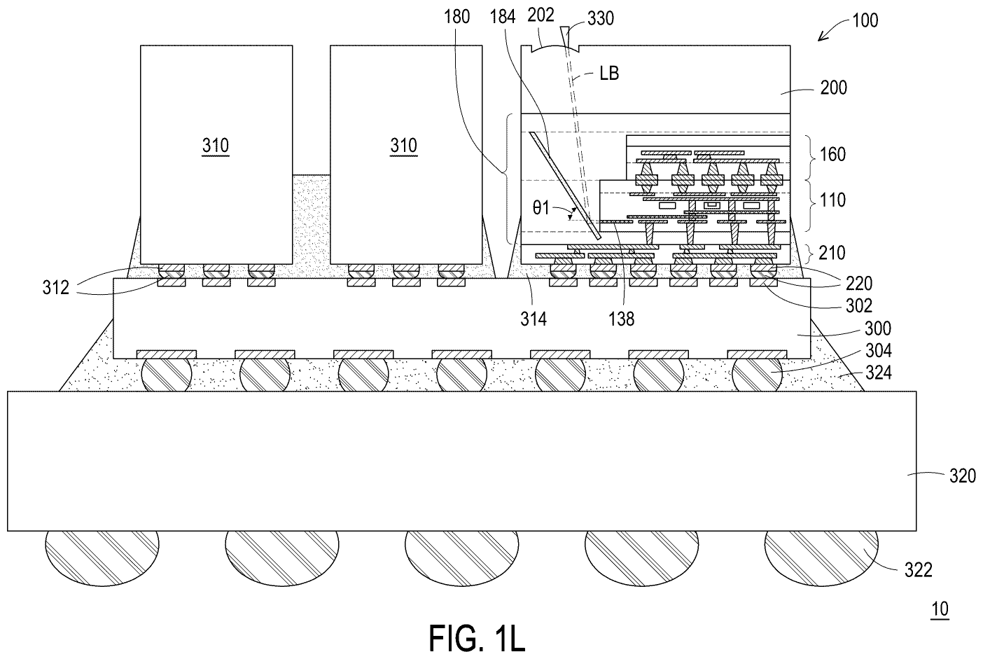

FIG. 1A to FIG. 1L are schematic cross-sectional views of various stages in a method of forming a semiconductor device according to some embodiments.

Referring to FIG. 1A, a carrier substrate C1 is provided, and a photonic wafer 104 is formed over the carrier substrate C1. In some embodiments, the carrier substrate C1 is a silicon substrate, a glass substrate, a ceramic substrate or any suitable carrier for carrying a semiconductor wafer or a reconstituted wafer for the manufacturing method of the package structure.

In some embodiments, a dielectric layer 102 is formed on the carrier substrate C1, and the photonic wafer 104 is formed on the dielectric layer 102. The dielectric layer 102 may include a light-transparent material such as silicon oxide, silicon nitride, silicon oxynitride, or the like. The photonic wafer 104 may include an interconnect structure 120 and optical devices 130. The interconnect structure 120 may include a dielectric layer 122 and conductive features 124 in the dielectric layer 122. The dielectric layer 122 may have a single-layer structure or a multilayer structure. The dielectric layer 122 may include silicon oxide, silicon nitride, germanium oxide, germanium nitride, a combination thereof, or the like, and may be formed using a deposition method such as chemical vapor deposition, atomic layer deposition, physical vapor deposition, a combination thereof, or the like. The conductive features 124 may include conductive vias and/or conductive lines. The conductive features 124 may be formed of a conductive material such as copper, cobalt, aluminum, gold, a combination thereof, or the like. The conductive features 124 may be formed by a damascene process, such as single damascene process, dual damascene process, or the like. In some embodiments, the interconnect structure 120 further includes through dielectric vias (TDVs) 126. The TDVs 126 are disposed in the dielectric layer 102 and the dielectric layer 122.

The optical devices 130 may include optical waveguides 132 and modulators 134. The optical waveguides 132 include ridge waveguides, rib waveguides, buried channel waveguides, diffused waveguides, the like, or a combination thereof. The modulators 134 include Mach-Zehnder silicon-photonic switches, microelectromechanical switches, micro-ring resonators, the like, or a combination thereof. However, the disclosure is not limited thereto. The optical devices 130 may further include couplers (e.g., grating couplers), directional couplers, optical, amplifiers, multiplexors, demultiplexors, optical-to-electrical converters (e.g., P-N junctions), electrical-to-optical converters, lasers, a combination thereof, or the like. In other words, any suitable optical devices 130 may be used. The optical devices 130 may include a dielectric material such as silicon nitride, III-V materials, lithium niobate materials, polymers, or the like. The optical devices 130 may be formed by forming a material and patterning the material layer into a desired shape using one or more photolithographic masking and etching processes. In some embodiments, some optical devices 130 such as the optical waveguides 132 and the modulators 134 are also referred to as a first active layer.

The optical devices 130 further includes optical couplers 136 and at least one edge coupler 138. As shown in FIG. 1A, the optical couplers 136 and the edge coupler 138 are arranged in order to receive and transmit optical signals into and out an active layer (not shown). In some embodiments, the optical couplers 136 and the edge coupler 138 are waveguides. The edge coupler 138 may be also referred to an edge waveguide. The optical devices 130 may include one or more edge couplers 138. The one or more edge couplers 138 may include one or more levels of edge couplers, wherein each level of the edge couplers 138 provide multiple optical paths, such as between about 20 and 80 optical paths, such as 40 optical paths. However, any suitable coupler may be utilized. The optical couplers 136 and the edge coupler 138 may include a dielectric material such as silicon nitride, III-V materials, lithium niobate materials, polymers, or the like. The optical couplers 136 and the edge coupler 138 may be formed by forming a material and patterning the material layer into a desired shape using one or more photolithographic masking and etching processes. In some embodiments, some optical devices 130 such as the optical couplers 136 and the edge coupler 138 are also referred to as a second active layer.

Referring to FIG. 1B, a portion of the dielectric layer 122 is removed, to form an optical path opening 139. The dielectric layer 122 may be removed by an etching process, or the like. In some embodiments, after the dielectric layer 122 is partially removed, a photonic die 110 is formed. The edge coupler 138 is disposed within the photonic die 110 and at an edge (or sidewall) 110s1 of the photonic die 110.

Referring to FIG. 1C, a dielectric layer 140 is formed to fill the optical path opening 139. In some embodiments, a surface (e.g., top surface) 140a of the dielectric layer 140 is substantially coplanar with a surface (e.g., top surface) 110a of the photonic die 110. The material and formation method of the dielectric layer 140 are the same as or similar to those of the dielectric layer 102, so the detailed description thereof is omitted herein. That is, the dielectric layer 140 may also have a light-transparent material. For example, the dielectric layer 102 and the dielectric layer 140 include the same material such as silicon oxide. In such embodiments, an interface does not exist or is hardly observed between the dielectric layer 102 and the dielectric layer 140. However, the disclosure is not limited. The dielectric layer 102 and the dielectric layer 140 may include different materials.

A bonding structure 150 is formed on the interconnect structure 120. In some embodiments, the bonding structure 150 includes at least one bonding dielectric layer 152 and a plurality of bonding conductive features. In some embodiments, the bonding dielectric layer 152 is a portion of the dielectric layer 122 or an additional dielectric layer formed on the dielectric layer 122. The bonding dielectric layer 152 includes silicon oxide, silicon nitride, a polymer or a combination thereof. The bonding conductive features are disposed in the bonding dielectric layer 152 and electrically connected with each other. In some embodiments, the bonding conductive features include bonding vias 154 electrically connected to the interconnect structure 120 and bonding pads 156 electrically connected to the bonding vias 154. The bonding conductive features may include tungsten (W), copper (Cu), a copper alloy, aluminum (Al), an aluminum alloy or a combination thereof. In some embodiments, a barrier layer (not shown) is disposed between the bonding conductive features and the bonding dielectric layer 152. The barrier layer includes Ta, TaN, Ti, TiN, CoW or a combination thereof, for example. In some embodiments, the bonding structure 150 is formed by multiple single damascene processes, a dual damascene process, an electroplating process, or the like.

Referring to FIG. 1D, an electronic die 160 is bonded to the photonic die 110. The electronic die 160 may include a semiconductor substrate 162, active and/or passive electric devices on an active side of the semiconductor substrate 162, an interconnect structure 164 on the active side of the semiconductor substrate 162 and a bonding structure 170. The semiconductor substrate 162 may be a substrate of silicon, doped or undoped or a semiconductor-on-insulator (SOI) substrate. The semiconductor substrate 162 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multilayered or gradient substrates, may also be used. The semiconductor substrate 162 has a front-side surface and a backside surface. In some embodiments, active devices (e.g., transistors, diodes, etc.), capacitors, resistors, the like, or a combination thereof, are formed in and/or on the front-side surface of the semiconductor substrate 162.

The interconnect structure 164 is formed over the front-side surface of the semiconductor substrate 162, and is used to electrically connect the devices (if any) of the semiconductor substrate 162. The interconnect structure 164 may include may include a dielectric layer 166 and conductive features 168 in the dielectric layer 166. The dielectric layer 166 may have a single-layer structure or a multilayer structure. The dielectric layer 166 may include silicon oxide, silicon nitride, germanium oxide, germanium nitride, a combination thereof, or the like, and may be formed using a deposition method such as chemical vapor deposition, atomic layer deposition, physical vapor deposition, a combination thereof, or the like. The conductive features 168 may include conductive vias and/or conductive lines. The conductive features 168 may be formed of a conductive material such as copper, cobalt, aluminum, gold, a combination thereof, or the like. The conductive features 168 may be formed by a damascene process, such as single damascene process, dual damascene process, or the like. In some embodiments, the interconnect structure 164 further includes through dielectric vias (TDV) (not shown).

In some embodiments, the bonding structure 170 includes at least one bonding dielectric layer 172 and a plurality of bonding conductive features. In some embodiments, the bonding dielectric layer 172 includes silicon oxide, silicon nitride, a polymer or a combination thereof. The bonding conductive features are disposed in the bonding dielectric layer 172 and electrically connected with each other. In some embodiments, the bonding conductive features include bonding vias 174 electrically connected to the interconnect structure 120 and bonding pads 176 electrically connected to the bonding vias 174. The bonding conductive features may include tungsten (W), copper (Cu), a copper alloy, aluminum (Al), an aluminum alloy or a combination thereof. In some embodiments, a barrier layer (not shown) is disposed between the bonding conductive features and the bonding dielectric layer 172. The barrier layer includes Ta, TaN, Ti, TiN, CoW or a combination thereof, for example. In some embodiments, the bonding structure 170 is formed by multiple single damascene processes, a dual damascene process, an electroplating process, or the like. In some embodiments, the photonic die 110 and the electronic die 160 are bonded together by a hybrid bonding including a metal-to-metal bonding and a dielectric-to-dielectric bonding. For example, the bonding pads 156 are bonded to the bonding pads 176, and the bonding dielectric layer 152 is bonded to the bonding dielectric layer 172. In an embodiment in which the electronic die 160 is bonded to the photonic die 110 of a photonic wafer, the hybrid bonding is also referred to as a chip on wafer (CoW) hybrid bonding.

Referring to FIG. 1E, a dielectric layer 178 is formed to encapsulate and cover the electronic die 160. The material and formation method of the dielectric layer 178 are the same as or similar to those of the dielectric layer 140, so the detailed description thereof is omitted herein. That is, the dielectric layer 178 may also have a light-transparent material. For example, the dielectric layers 102, 140 and 178 include the same material such as silicon oxide. In such embodiments, an interface does not exist or is hardly observed between the dielectric layers 102, 140 and the dielectric layers 140, 178. In some embodiments, the dielectric layers 102, 140 and 178 may be collectively referred to as an encapsulant 180. However, the disclosure is not limited. The dielectric layers 102, 140 and 178 may include different materials.

Referring to FIG. 1F, an opening 182 is formed in the encapsulant 180. For example, a portion of the encapsulant 180 is removed by an etching process such as dry etching process, wet etching process or any suitable process. The opening 182 is oriented at an angle θ1 (tilted) with respect to the edge coupler 138 of the photonic die 110. For example, the opening 182 is oriented at the angle θ1 (tilted) with respect to a surface (e.g., top surface) 138a of the edge coupler 138 of the photonic die 110. The angle θ1 may be any suitable angle as long as it is larger than the critical angle. The angle θ1 is an acute angle and thus is not 0° or 90°, and the angle θ1 is, for example, 45°. The opening 182 has a width in a range of 50 nm to 2000 nm along a horizontal direction and has a depth in a range of 50 nm to 200 um along a vertical direction, for example. In some embodiments, the opening 182 extends from a surface of the dielectric layer 178 into the dielectric layer 102 of the encapsulant 180. However, the disclosure is not limited thereto. The opening 182 may be extended into any depth of the encapsulant 180 lower than a surface (e.g., bottom surface) 138b opposite to the surface 138a of the edge coupler 138.

Referring to FIG. 1G and FIG. 1H, a reflector coupler 184 is formed in the opening 182. First, as shown in FIG. 1G, a material is filled in the opening 182. In some embodiments, the refractive index (RI) of the material of the reflector coupler 184 is higher than the RI of the surrounding materials such as the encapsulant 180. The material includes silicon, aluminum copper, copper, gold, aluminum, titanium nitride, a combination thereof, or the like. The material may be formed by a deposition process such as chemical vapor deposition, physical vapor deposition, plating, combinations of these, or the like.

Then, as shown in FIG. 1H, a planarizing process such as chemical mechanical polishing process is performed on the material, to form the reflector coupler 184. In some embodiments in which the opening 182 is filled and/or overfilled with a material, the material is planarized by a planarizing process such as chemical mechanical polishing process. In alternative embodiments in which the formation of the material does not fully fill the opening 182, the opening 182 may be filled and then planarized. The encapsulant 180 may be partially removed with the material.

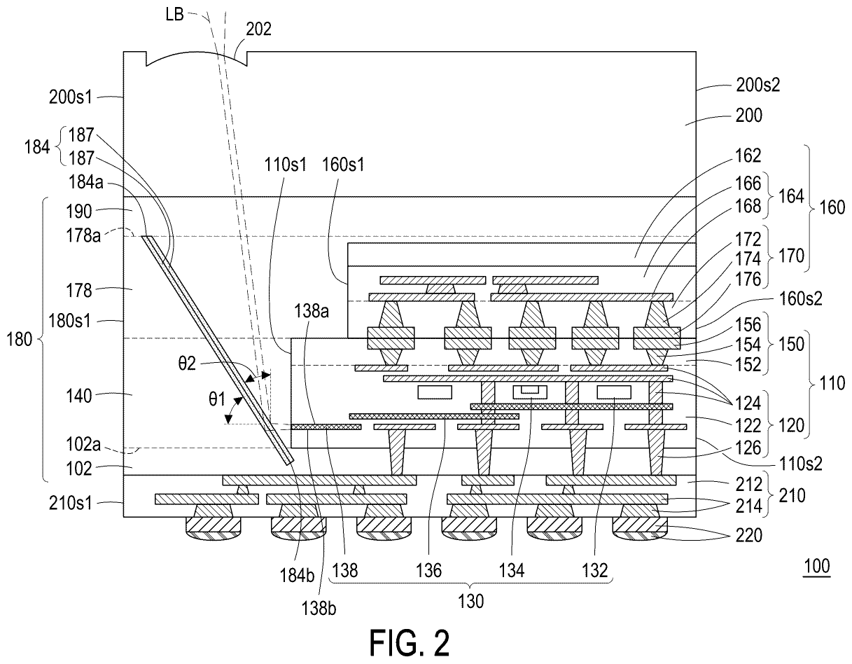

In some embodiments, the reflector coupler 184 includes a single layer of a reflective material such as silicon, aluminum copper, copper, gold, aluminum, titanium nitride, a combination thereof, or the like. In alternative embodiments, as shown in FIG. 2, the reflector coupler 184 includes a plurality of layers 187 forming a multilayer structure. For example, the reflector coupler 184 includes a plurality of higher-refractive layers and lower-refractive layers alternatingly arranged. Silicon and silicon nitride may be used to form a higher-refractive layer and a lower-refractive layer, respectively. Silicon and silicon oxide may be used to form a higher-refractive layer and a lower-refractive layer, respectively. For example, the reflector coupler 184 includes silicon while the encapsulant 180 has silicon oxide, silicon nitride or silicon oxynitride. However, any suitable material and any suitable process may be utilized.

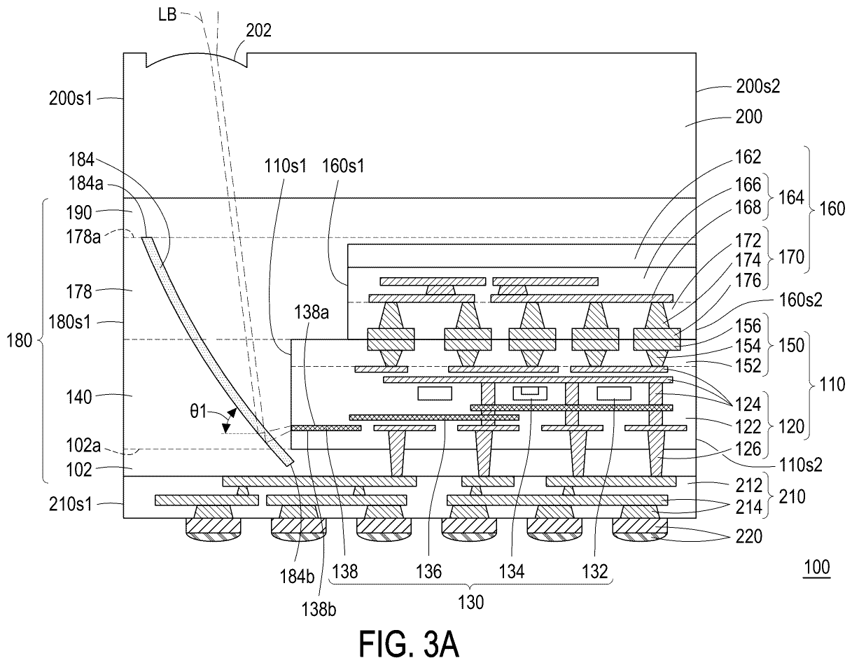

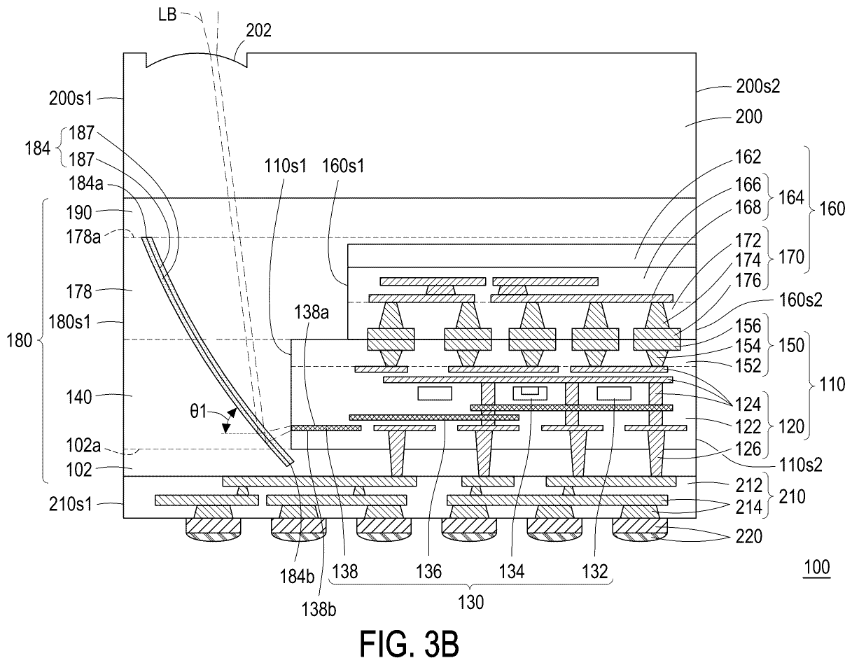

The reflector coupler 184 may have a reflecting surface 186 facing the sidewall 110s1 of the photonic die 110. The reflecting surface 186 reflects a light in or out the photonic die 110 (e.g., edge coupler or waveguide). For example, a light from the edge coupler 138 is reflected by the reflector coupler 184, or a light is reflected by the reflector coupler 184 and then incident into the edge coupler 138. The reflector coupler 184 is aligned with the edge coupler 138, for example, a portion of the reflecting surface 186 is aligned with the edge coupler 138. In some embodiments, the reflector coupler 184 has a mirror-like shape and thus also referred to as a mirror. In some embodiments, the reflecting surface 186 is planar. However, the disclosure is not limited thereto. In alternative embodiments, as shown in FIG. 3A and FIG. 3B, the reflecting surface 186 has a concave shape which is continuously curved. The reflector coupler 184 may have a single layer structure (FIG. 3A) or a multilayer structure including a plurality of layers 187 (FIG. 3B). In alternative embodiments (not shown), the reflector coupler 184 has a convex shape.

Referring to FIG. 1I, a dielectric layer 190 is formed to cover reflector coupler 184 and the electronic die 160. The material and formation method of the dielectric layer 190 are the same as or similar to those of the dielectric layer 178, so the detailed description thereof is omitted herein. That is, the dielectric layer 190 may also have a light-transparent material. For example, the dielectric layers 102, 140, 178 and 190 include the same material such as silicon oxide. In such embodiments, an interface does not exist or is hardly observed between the interfacing dielectric layers 102, 140, 178 and 190. In some embodiments, the dielectric layers 102, 140, 178 and 190 may be collectively referred to as the encapsulant 180. In some embodiments in which the encapsulant 180 includes oxide, the encapsulant 180 is also referred to as an oxide region. However, the disclosure is not limited. The dielectric layers 102, 140, 178 and 190 may include different materials.

Then, a support die 200 is formed. In some embodiments, the support die 200 is bonded to the dielectric layer 190. For example, the support die 200 is bonded to the semiconductor substrate 162 of the electronic die 160 through the dielectric layers 178, 190 therebetween. In some embodiments, the support die 200 is a semiconductor die, such as a silicon die. The support die 200 may include elementary semiconductor such as silicon, germanium and/or a compound semiconductor such as silicon germanium, silicon carbide, gallium arsenic, indium arsenide, gallium nitride or indium phosphide. In some embodiments, the support die 200 is also referred to as a support substrate such as silicon substrate or a carrier substrate. In some embodiments, the support die 200 is one of the support dies of a carrier wafer such as a silicon carrier wafer. In such embodiments, the bonding between the support die 200 and the formed structure is also referred to as wafer on wafer bonding.

In some embodiments, the support die 200 includes an optical lens 202. The optical lens 202 may be embedded in the support die 200 and disposed corresponding to the reflecting surface 186 of the reflector coupler 184. For example, the optical lens 202 and the photonic die 110 are disposed at opposite sides of the electronic die 160. The optical lens 202 is configured to condense a light beam in a desired cross section, or focus a light beam in the desired direction. In some embodiments, the optical lens 202 has an optical recessed feature. In some embodiments, the optical lens 202 has a substantially vertical sidewall and a convex bottom. The shape of the optical lens 202 may be designed to have the desired curvature for focusing a light beam to the underlying optical component.

Referring to FIG. 1J, a redistribution layer (RDL) structure 210 and conductive connectors 220 are formed on the photonic die 110. For example, the carrier substrate C1 is removed, and the structure de-bonded from the carrier substrate C1 is flipped upside-down. Then, the RDL structure 210 is formed over the encapsulant 180 and the photonic die 110. The RDL structure 210 is electrically connected to the photonic die 110, and the conductive connectors 220 are electrically connected to the RDL structure 210. The photonic die 110 is disposed between the electronic die 160 and the RDL structure 210. In some embodiments, The RDL structure 210 may include an insulating layer 212 and conductive features 214 in the insulating layer 212. The insulating layer 212 may have a single-layer structure or a multilayer structure. In some embodiments, the insulating layer 212 may include a photo-sensitive material such as polyimide (PI), polybenzoxazole (PBO), benzocyclobutene (BCB), a combination thereof, or the like. The insulating layer 212 may include same material or different materials. In an embodiment, the insulating layer 212 is also referred to as a molding region. In some embodiments, the conductive features 214 includes copper, nickel, titanium, a combination thereof, or the like. The conductive features 214 may be formed of a conductive material such as copper, cobalt, aluminum, gold, a combination thereof, or the like. The RDL structure 210 may be formed by a damascene process, such as single damascene process, dual damascene process, or the like. In some embodiments, the insulating layer 212 has a multilayer structure, and the conductive features 214 are arranged into a plurality of metallization layers. However, the disclosure is not limited thereto. The RDL structure 210 may have any suitable configurations. In some embodiments, the conductive connectors 220 include metal pillars and solder regions, which may be used for solder bonding. In the illustrated embodiment, the conductive connectors 220 include C4 bumps or the like.

In some embodiments, the formed structure including a plurality of die regions in which the electronic dies 160 and the photonic dies 110 are stacked is singulated, to form a plurality of package components 100. However, the disclosure is not limited thereto. The package component 100 may be formed by any suitable method and have any suitable configurations.

Referring to FIG. 1K and FIG. 1L, the structure of FIG. 1J is tuned upside down (FIG. 1K), and then the package component 100 is bonded to an interconnect substrate 300 (FIG. 1L). The package component 100 is bonded to the interconnect substrate 300 using the conductive connectors 220 of the package component 100 and conductive connectors 302 of the interconnect substrate 300. The interconnect substrate 300 may be an interposer. In some embodiments, a plurality of package components such as package components 310 are also bonded to the interconnect substrate 300 along with the package component 100. The package components 310 may be non-optical dies. For example, the package components 310 are respectively a logic die (e.g., central processing unit (CPU), graphics processing unit (GPU), system-on-a-chip (SoC), application processor (AP), microcontroller, etc.), a memory die (e.g., high bandwidth memory (HBM) die, dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, a switch die, or combinations thereof. The package components 310 may be bonded to the conductive connectors 302 through conductive connectors 312. In the illustrated embodiment, the conductive connectors 312 include ball grid array (BGA) connectors or the like.

After the bonding, the underfill 314 may be formed aside the conductive connectors 220, the conductive connectors 312, the conductive connectors 302 and the solder joints (not shown) therebetween, and in a gap between the interconnect substrate 300 and the package component 100 and between the interconnect substrate 300 and the package components 310. An underfill 314 may be formed of an underfill material such as a molding compound, epoxy, or the like. In alternative embodiments, an encapsulant may be formed over the interconnect substrate 300 to encapsulate the package component 100, the package components 310 and the underfill 314. The encapsulant may be applied by compression molding, transfer molding, or the like. The interconnect substrate 300 may be further bonded to another interconnect substrate 320 through the conductive connectors 304, and an underfill 324 may be formed aside the conductive connectors 304. The bonding may be achieved through hybrid bonding, solder bonding, or the like. The interconnect substrate 320 may be a package substrate, a printed circuit board, a package, or the like. In some embodiments, the interconnect substrate 320 include conductive connectors 322. In the illustrated embodiment, the conductive connectors 322 include solder balls.

An optical fiber 330 may be attached to optical lens 202, which is filled with an optical glue. The optical fiber 330 is a vertical fiber, for example. Then, a package 10 such as a Compact Universal Photonic Engine (COUPE) or other photonic engine system is formed. It is noted that the package 10 including the package component 100 may have any suitable configurations. For example, the structure and the number of the package components 310 are varied according to the requirements.

In some embodiments, as shown in FIG. 1K, the package component 100 includes the photonic die 110, the electronic die 160 bonded to the photonic die 110, the encapsulant 180 encapsulating the photonic die 110 and the electronic die 160, and the reflector coupler 184 in the encapsulant 180. The reflector coupler 184 is disposed outside the photonic die 110 and oriented at an angle θ1 (tilted) with respect to the edge coupler 138 of the photonic die 110. For example, the reflecting surface 186 of the reflector coupler 184 is oriented at a first angle θ1 (tilted) with respect to the surface (e.g., facing the optical lens 202) 138a of the edge coupler 138 of the photonic die 110. The first angle θ1 is an acute angle and thus is not 0° or 90°, and the first angle θ1 is, for example, 45°. The reflector coupler 184 (e.g., the reflecting surface 186 of the reflector coupler 184) is also oriented at a second angle θ2 (tilted) with respect to the sidewall 110s1 of the photonic die 110. The second angle θ2 is an acute angle and thus is not 0° or 90°, and the second angle θ2 is, for example, 45°. A total of the first angle θ1 and the second angle θ1 is substantially equal to 90°, for example. However, the disclosure is not limited thereto. In some embodiments, the reflector coupler 184 is entirely disposed outside the photonic die 110. However, the disclosure is not limited thereto.

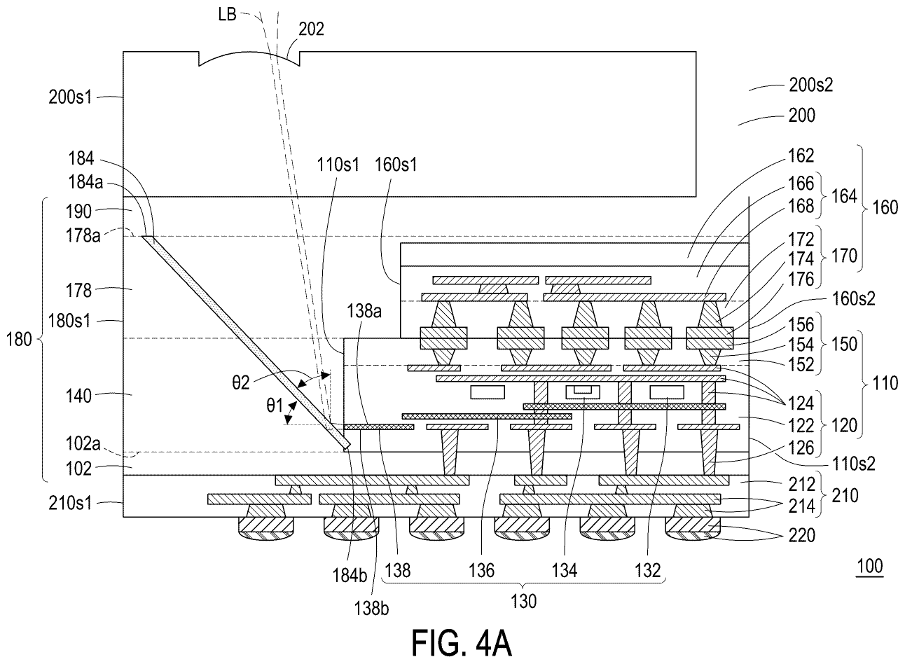

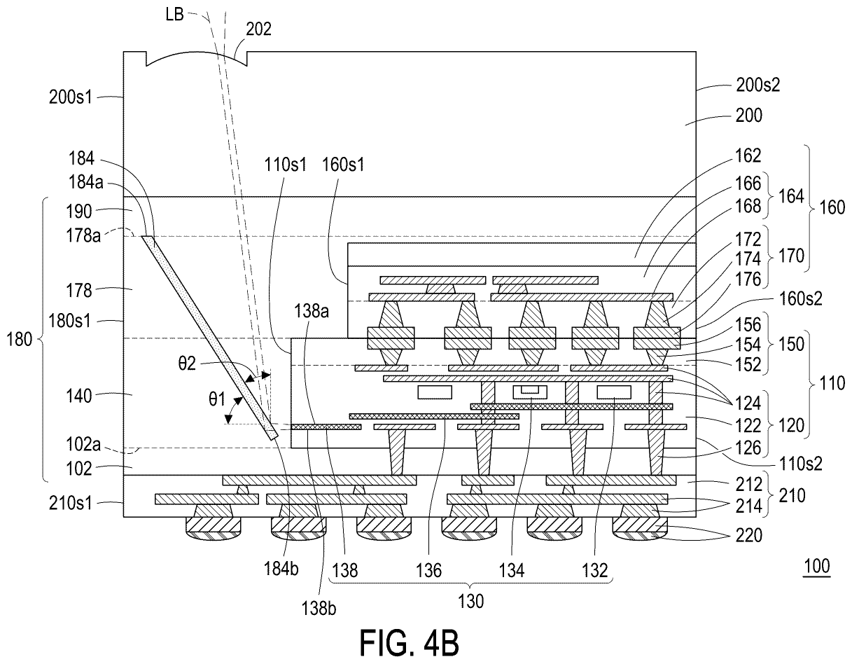

In some embodiments, the reflector coupler 184 extends between opposite surfaces of the encapsulant 180. For example, the reflector coupler 184 extends from a surface (e.g., top surface) 178a of the dielectric layer 178 into the dielectric layer 102 of the encapsulant 180. A surface (e.g., facing the optical lens 202) 184a of the reflector coupler 184 may be substantially coplanar with the surface (e.g., top surface) 178a of the dielectric layer 178, and a surface (e.g., away from the support die 200) 184b of the reflector coupler 184 extends beyond a surface (e.g., top surface) 102a of the dielectric layer 102 under the dielectric layer 178. However, the disclosure is not limited thereto. The reflector coupler 184 may be extended into any depth of the encapsulant 180 lower than a surface (e.g., away from the optical lens 202) 138b opposite to the surface 138a of the edge coupler 138 as long as the light in and out the edge coupler 138 is redirected from and to the optical lens 202. For example, the surface (e.g., bottom surface) 184b of the reflector coupler 184 is disposed between opposite surfaces of the dielectric layer 102. In some embodiments, the reflector coupler 184 is disposed in the dielectric layers 140, 178 and further extends into the dielectric layer 102 directly under the dielectric layers 140, 178. In some embodiments, the reflector coupler 184 further extends under the edge coupler 138. In alternative embodiments, as shown in FIG. 4A, the reflector coupler 184 is disposed in the dielectric layers 140, 178 without extending into the dielectric layer 102. In alternative embodiments, as shown in FIG. 4B, the reflector coupler 184 is partially disposed outside the photonic die 110 and partially disposed in the photonic die 110. For example, the reflector coupler 184 is partially extended in the encapsulant 180 and partially extended into the dielectric layer 122 of the photonic die 110. In some embodiments, the encapsulant 180 (e.g., dielectric layers 102, 140, 178) encapsulates the reflector coupler 184 and physically contacts the reflecting surface 186 of the reflector coupler 184.

In some embodiments, the package component 100 further includes the support die 200 and the RDL structure 210 at opposite sides of the photonic die 110 and the electronic die 160. The support die 200 may cover the reflector coupler 184, the electronic die 160 and the encapsulant 180. The reflector coupler 184 is disposed between opposite sidewalls 200s1, 200s2 of the support die 200, and one of the sidewalls 200s1, 200s2 may be substantially flush with a sidewall 110s1, 160s1 of at least one of the photonic die 110 and the electronic die 160. For example, the reflector coupler 184 is disposed adjacent to the sidewalls 110s1, 160s1, 200s1, 210s1 of the photonic die 110, the electronic die 160, the support die 200 and the RDL structure 210. In some embodiments, the reflector coupler 184 is disposed between the sidewall 200s1 of the support die 200 and the sidewall 110s1 of the photonic die 110. The sidewalls 110s2, 160s2, 200s2, 210s2 opposite to the sidewalls 110s1, 160s1, 200s1, 210s1 of the photonic die 110, the electronic die 160, the support die 200 and the RDL structure 210 may be substantially flush. The sidewall 200s1 of the support die 200 is substantially flush with a sidewall 180s1 of the encapsulant 180, for example. However, the disclosure is not limited thereto. In alternative embodiments, the sidewalls 110s2, 160s2, 200s2 of the photonic die 110, the electronic die 160 and the support die 200 may be not flush, and the sidewalls 110s2, 160s2, 200s2 of the photonic die 110, the electronic die 160 and the support die 200 are optionally encapsulated by the encapsulant (e.g., encapsulant 180).

The reflector coupler 184 is used for reflecting light. For example, as shown in FIG. 1K and FIG. 1L, when a light beam LB is projected from the optical fiber 330 (FIG. 1L) onto the reflector coupler 184, the light beam LB is reflected, and is projected on the edge couplers 138 as optical signals. In some embodiments, the reflector coupler 184 redirects the light beam horizontally into the edge couplers 138. The optical signals are transported through the optical waveguides 132 in the photonic die 110. The light beam LB may be reflected by the reflector coupler 184 back to the optical fiber 330 again, and redirected. That is, the direction (i.e., beam direction) of the light beam LB from the edge couplers 138 is turned by the reflector coupler 184, or the light beam LB is turned by the reflector coupler 184 and then incident into the edge couplers 138.

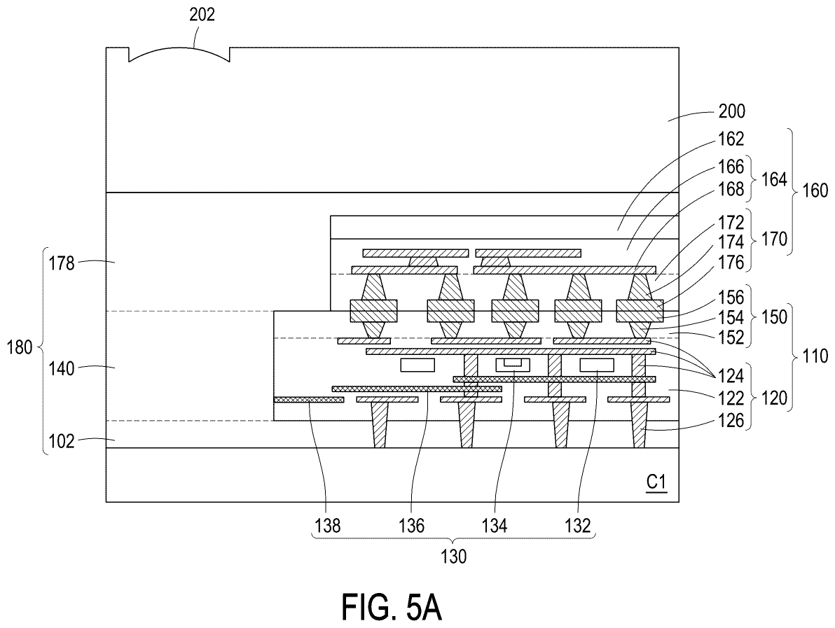

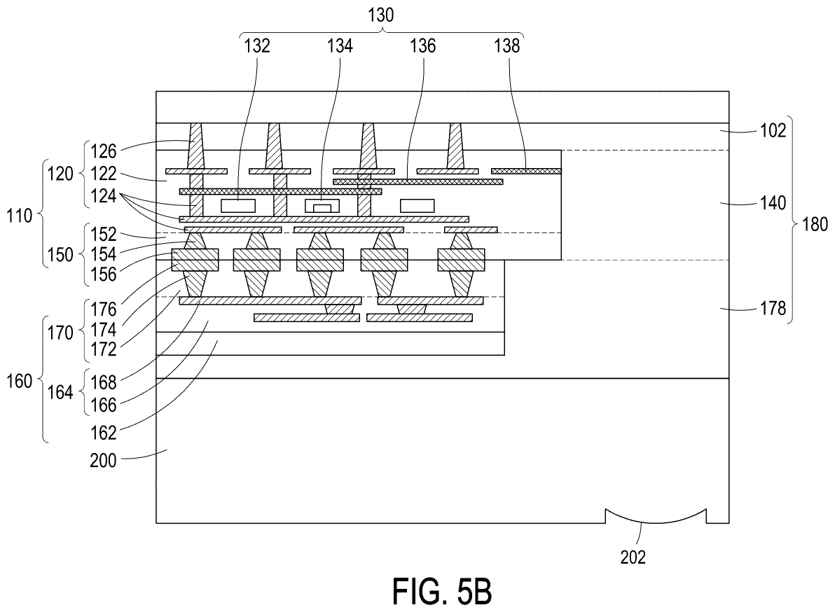

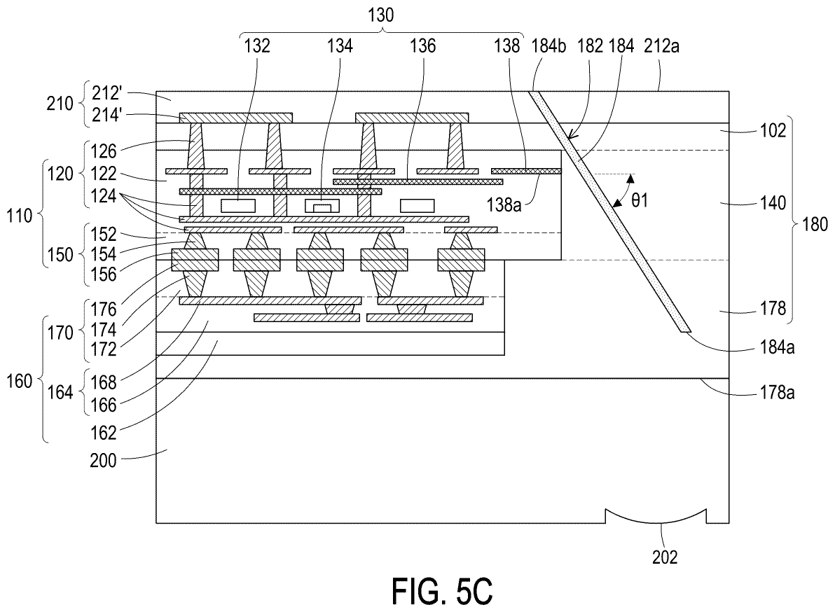

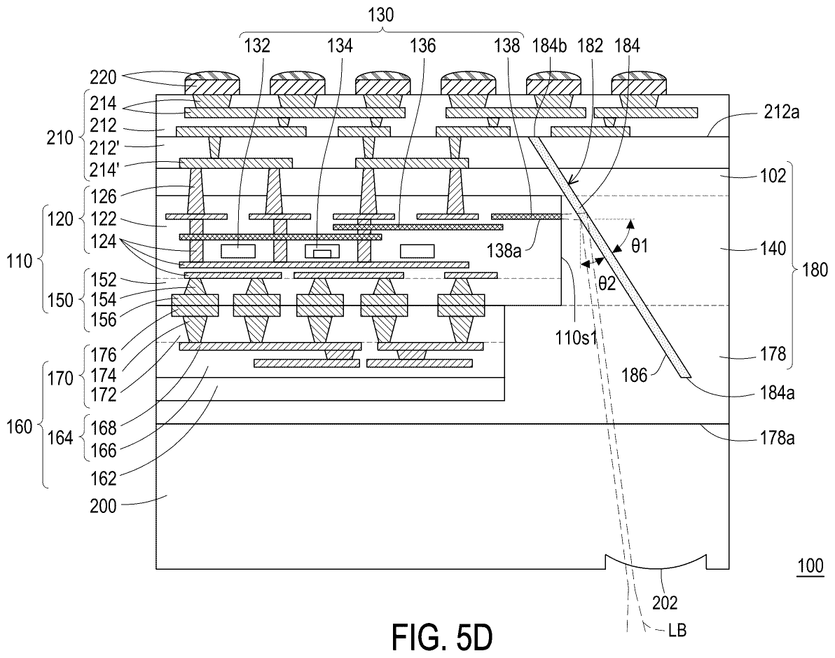

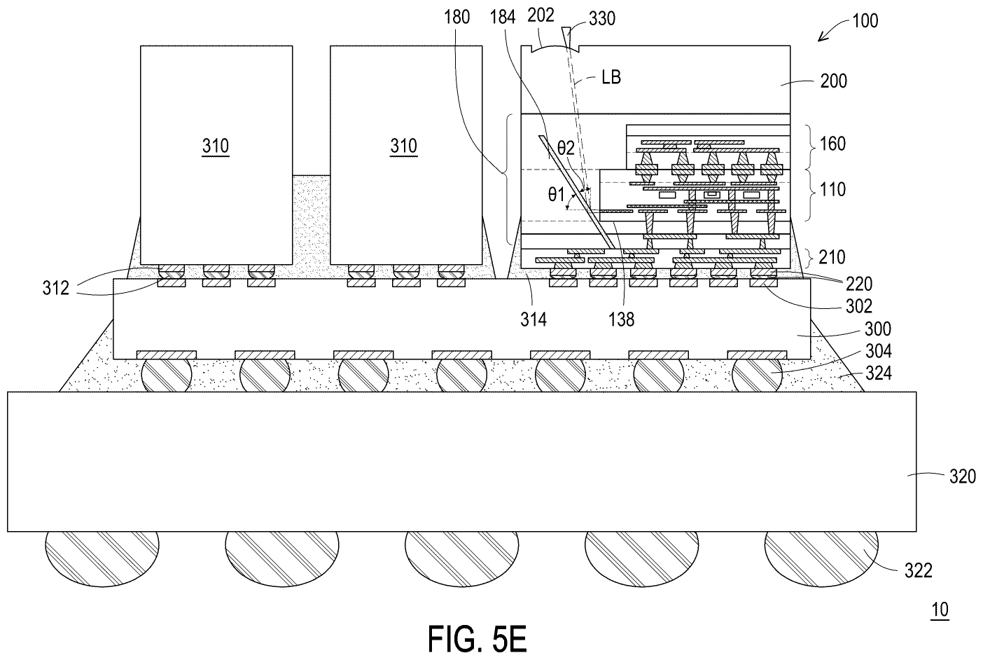

FIG. 5A to FIG. 5E are schematic cross-sectional views of various stages in a method of forming a semiconductor device according to some embodiments. The semiconductor device of FIG. 5E is similar to that of FIG. 1L, and the difference lies in that the reflector coupler further extends into the RDL structure.

Referring to FIG. 5A, a photonic die 110 and an electronic die 160 are bonded and encapsulated by an encapsulant 180. The material, structure and formation method of the photonic die 110, the electronic die 160 and the encapsulant 180 are similar to those of FIG. 1A to FIG. 1E, so the detailed description thereof is omitted herein. The encapsulant 180 includes dielectric layers 102, 140 and 178, for example. However, the disclosure is not limited thereto. The encapsulant 180 may include less or more dielectric layers.

Then, a support die 200 is bonded to the encapsulant 180 over the photonic die 110 and the electronic die 160. The structure and formation method of the support die 200 are similar to those of the support die 200 described above, so the detailed description thereof is omitted herein. In some embodiments, the support die 200 is directly bonded to the dielectric layer 178 of the encapsulant 180. For example, the support die 200 is bonded to the semiconductor substrate 162 of the electronic die 160 through the dielectric layer 178 therebetween. In other words, the dielectric layer 178 may contact both the support die 200 and the electronic die 160.

Referring to FIG. 5B, a portion of a RDL structure 210 is formed over the encapsulant 180 and the photonic die 110. For example, the carrier substrate C1 is removed, and the structure de-bonded from the carrier substrate C1 is flipped upside-down. Then, an insulating layer 212′ of the RDL structure 210 is formed on the dielectric layer 102. In some embodiments, the insulating layer 212′ is formed on the dielectric layer 102. The material and formation method of the insulating layer 212′ are the same as or similar to those of the insulating layer 212 described above, so the detailed description thereof is omitted herein. The insulating layer 212′ may have a single-layer structure or a multilayer structure. In some embodiments, the insulating layer 212′ is a single-layer structure. In some embodiments, the material of the insulating layer 212′ is different from the material of the dielectric layer 102. For example, the dielectric layer 102 includes silicon oxide, and the insulating layer 212′ includes polyimide.

Referring to FIG. 5C, an opening 182 is formed in the insulating layer 212′ and the encapsulant 180, and a reflector coupler 184 is formed in the opening 182. The formation method of the opening 182 and the material, structure and formation method of the reflector coupler 184 are the same as or similar to those of the opening 182 and the reflector coupler 184 described above, so the detailed description thereof is omitted herein. For example, the opening 182 is formed in the insulating layer 212′ and the encapsulant 180 by removing portions of the insulating layer 212′ and the encapsulant 180. The removal process is an etching process such as dry etching process or wet etching process or any suitable process. Then, a material of the reflector coupler 184 is formed in the opening 182, and a planarization process is performed to remove excess material of the reflector coupler 184 and optionally a portion of the insulating layer 212′.

The reflector coupler 184 is oriented at an angle θ1 (tilted) with respect to the edge coupler 138 of the photonic die 110. For example, the reflector coupler 184 is oriented at the angle θ1 (tilted) with respect to a surface (e.g., top surface) 138a of the edge coupler 138 of the photonic die 110. The angle θ1 may be any suitable angle as long as it is larger than the critical angle. The angle θ1 is an acute angle and thus is not 0° or 90°, and the angle θ1 is, for example, 45°.

In some embodiments, the reflector coupler 184 extends from a surface 212a of the insulating layer 212′ into the encapsulant 180. For example, the reflector coupler 184 extends between the surface 212a of the insulating layer 212′ and a surface 180a of the encapsulant 180 (e.g., surface 178a of the dielectric layer 178). In some embodiments, a surface (e.g., away from the support die 200) 184b of the reflector coupler 184 is substantially coplanar with the surface (e.g., top surface) 212a of the insulating layer 212', and a surface 184a (e.g., facing the optical lens 202) of the reflector coupler 184 is between a surface 138a of the edge coupler 138 and the surface 178a of the dielectric layer 178. In other words, the reflector coupler 184 may be extended into any depth of the encapsulant 180 from the surface (e.g., top surface) 212a of the insulating layer 212′ as long as the light in and out the edge coupler 138 is redirected from and to the optical lens 202.

In some embodiments, conductive features 214′ are formed in the insulating layer 212′. The material, structure and formation method of the conductive features 214′ are the same as or similar to those of the conductive features 214 described above, so the detailed description thereof is omitted herein. The conductive features 214′ are electrically connected to the interconnect structure 120 of the photonic die 110. For example, the conductive features 214′ are conductive lines or conductive pads electrically connected to the TDVs 126 of the interconnect structure 120. In some embodiments, the conductive features 214′ are formed before the formation of the reflector coupler 184 (e.g., the opening 182). Thus, during the formation of the reflector coupler 184, the conductive features 214′ may be protected by the insulating layer 212′ thereover and would not be influenced by the processes for formation of the opening 182 and/or the reflector coupler 184. However, the disclosure is not limited thereto. The conductive features 214′ in the insulating layer 212′ may have any suitable configurations and may be partially or entirely formed after the formation of the reflector coupler 184 (e.g., the opening 182).

Referring to FIG. 5D, remaining portions of the RDL structure 210 are formed on the insulating layer 212′. For example, an insulating layer 212 and respective conductive features 214 are formed on the insulating layer 212′. Thus, the RDL structure 210 is finished. In some embodiments, the reflector coupler 184 is covered by the insulating layer 212 or the conductive feature 214 thereon. The material, structure and formation method of the insulating layer 212 and the conductive features 214 are the same as or similar to those of the insulating layer 212 and the conductive features 214 described above, so the detailed description thereof is omitted herein. In some embodiments, the insulating layer 212 has a multilayer structure, and the conductive features 214′, 214 are arranged into a plurality of metallization layers. As shown in FIG. 5D, some conductive features 214 are further formed in the insulating layer 212′ to electrically connect to the conductive features 214′. Thus, the RDL structure 210 may be electrically connected to the photonic die 110 through the conductive features 214′ and the TDVs 126. However, the disclosure is not limited thereto. The RDL structure 210 may include any suitable configurations.

Then, conductive connectors 220 are formed on the RDL structure 210, to form a package component 100. The material and formation method of the conductive connectors 220 are the same as or similar to those of the conductive connectors 220 described above, so the detailed description thereof is omitted herein.

In some embodiments, the reflector coupler 184 is disposed outside the photonic die 110 in the encapsulant 180 and the insulating layer 212′ of the RDL structure 210. The reflector coupler 184 is oriented at an angle θ1 (tilted) with respect to the edge coupler 138 of the photonic die 110. For example, the reflecting surface 186 of the reflector coupler 184 is oriented at a first angle θ1 (tilted) with respect to the surface (e.g., facing the optical lens 202) 138a of the edge coupler 138 of the photonic die 110. The first angle θ1 is an acute angle and thus is not 0° or 90°, and the first angle θ1 is, for example, 45°. The reflector coupler 184 (e.g., the reflecting surface 186 of the reflector coupler 184) is also oriented at a second angle θ2 (tilted) with respect to a sidewall 110s1 of the photonic die 110. The second angle θ2 is an acute angle and thus is not 0° or 90°, and the second angle θ2 is, for example, 45°. A total of the first angle θ1 and the second angle θ1 is substantially equal to 90°, for example. However, the disclosure is not limited thereto.

Referring to FIG. 5E, the package component 100 is bonded to an interconnect substrate 300 along with package components 310. The interconnect substrate 300 may be further bonded to another interconnect substrate 320. An optical fiber 330 may be attached to optical lens 202. The configuration and formation of the interconnect substrates 300, 320, the package components 310 and the optical fiber 330 are the same as or similar to those of the interconnect substrates 300, 320, the package components 310 and the optical fiber 330 described above, so the detailed description thereof is omitted herein.

The reflector coupler 184 is used for reflecting light. For example, as shown in FIG. 5D and FIG. 5E, when a light beam LB is projected from the optical fiber 330 (FIG. 5E) onto the reflector coupler 184, the light beam LB is reflected, and is projected on the edge couplers 138 as optical signals. In some embodiments, the reflector coupler 184 redirects the light beam horizontally into the edge couplers 138. The optical signals are transported through the optical waveguides 132 in the photonic die 110. The light beam LB may be reflected by the reflector coupler 184 back to the optical fiber 330 again, and redirected. That is, the direction (i.e., beam direction) of the light beam LB from the edge couplers 138 is turned by the reflector coupler 184, or the light beam LB is turned by the reflector coupler 184 and then incident into the edge couplers 138.

In some embodiments, the reflector coupler is formed after the formation of the support die. In other words, the reflector coupler may be formed after or before the formation of the support die and/or the RDL, and the reflector coupler may be formed with a desire depth in the encapsulant and optionally the insulating layer(s) of the RDL.

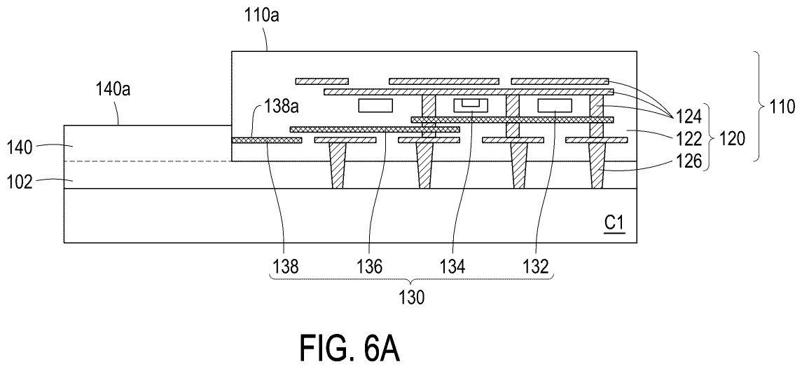

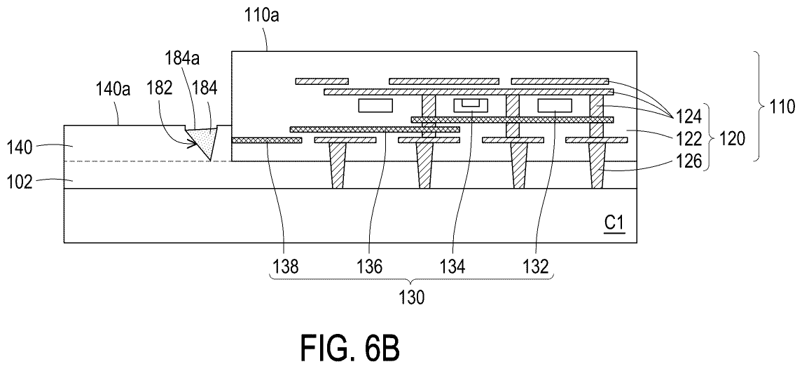

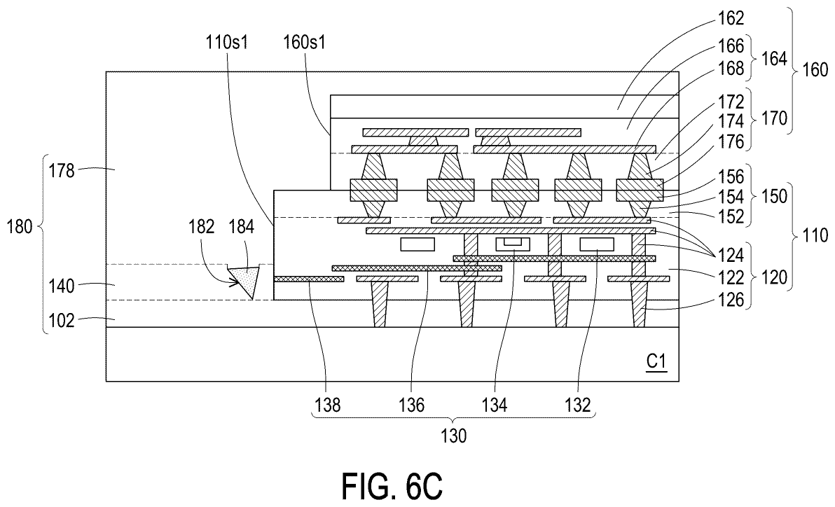

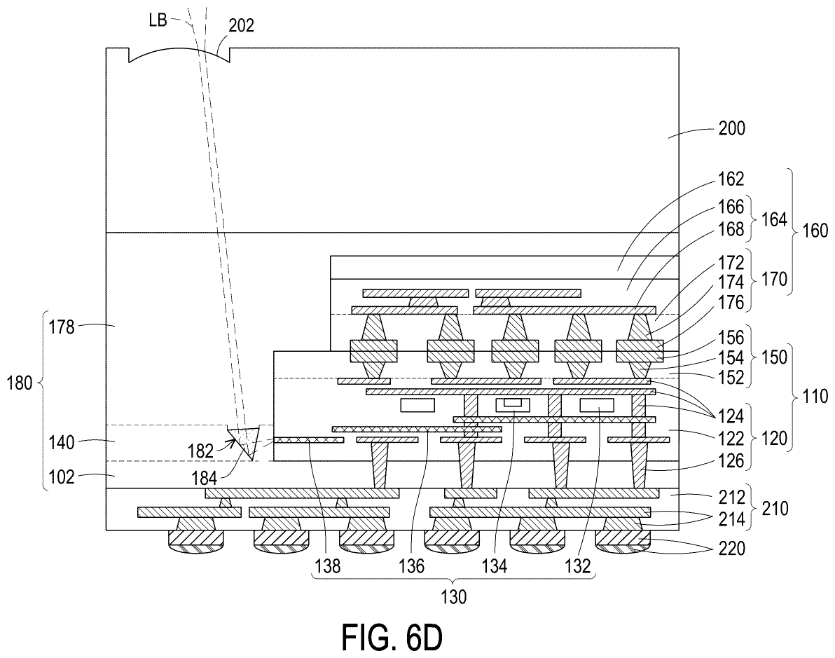

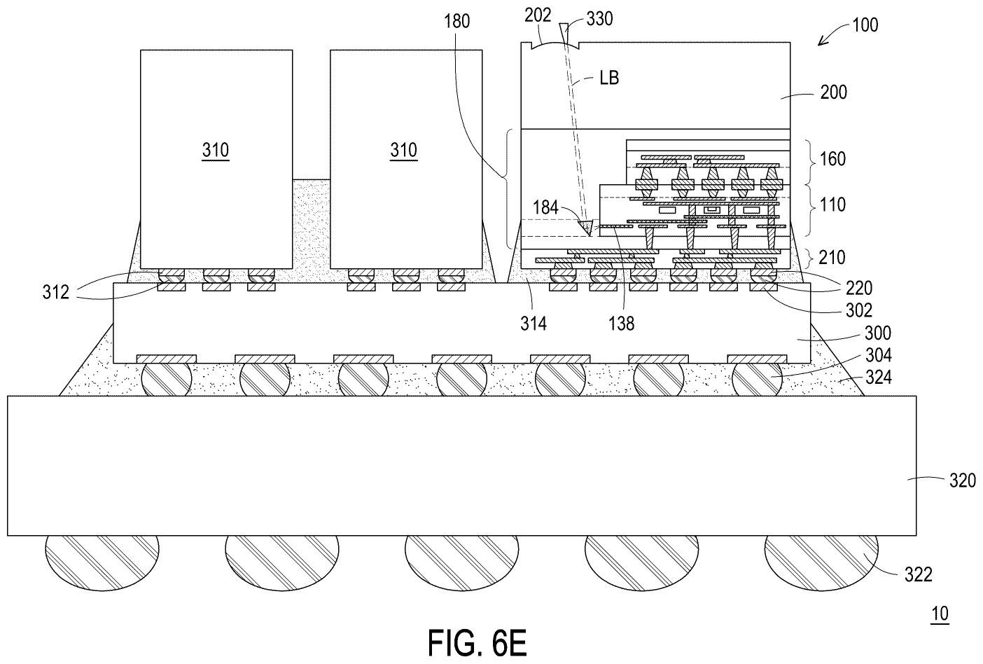

FIG. 6A to FIG. 6E are schematic cross-sectional views of various stages in a method of forming a semiconductor device according to some embodiments. The semiconductor device of FIG. 6E is similar to that of FIG. 1L, and the difference lies in that the configuration of the reflector coupler.

Referring to FIG. 6A, a dielectric layer 102 and a photonic die 110 is formed over a carrier substrate C1. The material and formation method of the dielectric layer 102 and the photonic die 110 are the same as or similar to those of the dielectric layer 102 and the photonic die 110 with reference to FIG. 1A and FIG. 1B, so the detailed description thereof is omitted herein.

Then, a dielectric layer 140 is formed aside the photonic die 110. In some embodiments, a thickness of the dielectric layer 140 is determined by a position of the edge coupler 138 of the photonic die 110 and a height of the reflector coupler 184 to be formed. For example, a surface 140a (e.g., top surface) of the dielectric layer 140 is higher than a surface 138a (e.g., top surface) of the edge coupler 138 and lower than a surface 110a (e.g., top surface) of the photonic die 110. The dielectric layer 140 may have a single-layer structure or a multilayer structure. The material and formation method of the dielectric layer 140 are the same as or similar to those of the dielectric layer 140 described above, so the detailed description thereof is omitted herein.

Referring to FIG. 6B, the reflector coupler 184 is formed in the dielectric layer 140. First, an opening is formed in the dielectric layer 140 by removing a portion of the dielectric layer 140. The opening has a prism-like shape or the like. The removal process is an etching process such as dry etching process, wet etching process or any suitable process. Then, the reflector coupler 184 may be formed in the opening by filling the opening with a material by a deposition process or placing a prism in the opening. The material and the deposition process of the reflector coupler 184 are the same as or similar to those of the reflector coupler 184 described above, so the detailed description thereof is omitted herein. In some embodiments, after the material is filled, a top surface 184a of the reflector coupler 184 may be adjusted, and thus the top surface 184a of the reflector coupler 184 is inclined or substantially flat based on the requirements. For example, as shown in FIG. 6B, the top surface 184a of the reflector coupler 184 is inclined and lower than the top surface 140a of the dielectric layer 140. The reflector coupler 184 is aligned with the edge coupler 138, for example. However, the disclosure is not limited thereto. In some embodiments, the reflector coupler 184 has a prism-like shape and thus may be also referred to as a prism. However, the reflector coupler 184 may have any suitable shapes and/or configurations.

Referring to FIG. 6C, after the formation of the reflector coupler 184, an electronic die 160 is bonded to the photonic die 110. Then, a dielectric layer 178 is formed to encapsulate the photonic die 110 and the electronic die 160 and covers the electronic die 160 and the reflector coupler 184, for example. In some embodiments, a portion of the dielectric layer 178 extends into the dielectric layer 140 and contacts the surface 184a of the reflector coupler 184. The material, structure and formation method of the electronic die 160 and the dielectric layer 178 are the same as or similar to those of the electronic die 160 and the dielectric layer 178 described above, so the detailed description thereof is omitted herein. In some embodiments, the dielectric layer 178 extends along both the sidewalls 110s1, 160s1 of the photonic die 110 and the electronic die 160. The dielectric layer 178 may have a single-layer structure or a multilayer structure. In some embodiments, the reflector coupler 184 is encapsulated by an encapsulant 180 including the dielectric layers 102, 140, 178. Then, a support die 200 is formed, and the carrier substrate C1 is removed. The structure and formation method of the support die 200 are similar to those of the support die 200 described above, so the detailed description thereof is omitted herein.

Referring to FIG. 6D, a RDL structure 210 and conductive connectors 220 are formed, to form a package component 100. The material, structure and formation method of the RDL structure 210 and the conductive connectors 220 are the same as or similar to those of the RDL structure 210 and the conductive connectors 220 described above, so the detailed description thereof is omitted herein.

Referring to FIG. 6E, the package component 100 is bonded to an interconnect substrate 300 along with package components 310. The interconnect substrate 300 may be further bonded to another interconnect substrate 320. An optical fiber 330 may be attached to optical lens 202. The configuration and formation of the interconnect substrates 300, 320, the package components 310 and the optical fiber 330 are the same as or similar to those of the interconnect substrates 300, 320, the package components 310 and the optical fiber 330 described above, so the detailed description thereof is omitted herein.

The reflector coupler 184 is used for reflecting light. For example, as shown in FIG. 6D and FIG. 6E, when a light beam LB is projected from the optical fiber 330 (FIG. 6E) onto the reflector coupler 184, the light beam LB is reflected, and is projected on the edge couplers 138 as optical signals. The optical signals are transported through the optical waveguides 132 in the photonic die 110. The light beam LB may be reflected by the reflector coupler 184 back to the optical fiber 330 again, and redirected. That is, the direction (i.e., beam direction) of the light beam LB from the edge couplers 138 is turned by the reflector coupler 184, or the light beam LB is turned by the reflector coupler 184 and then incident into the edge couplers 138.

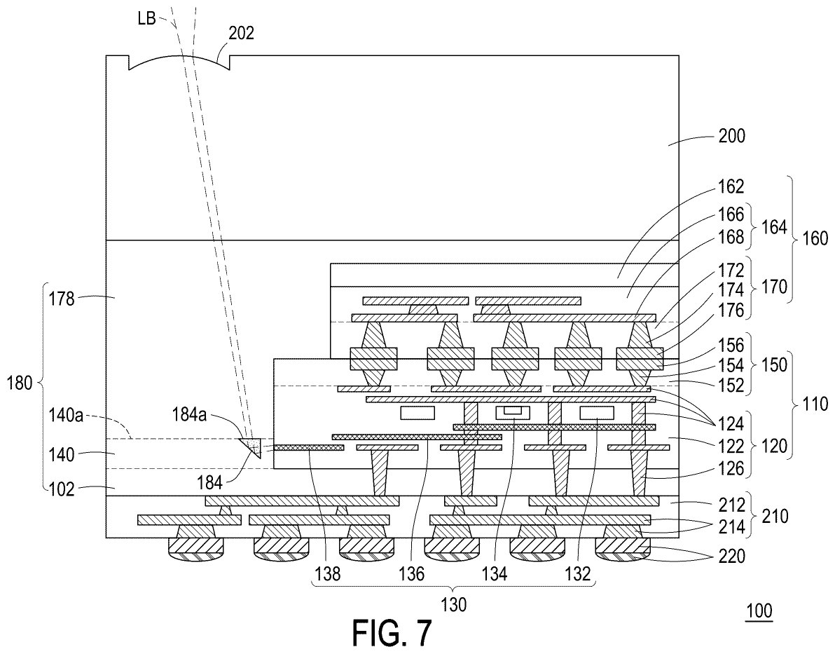

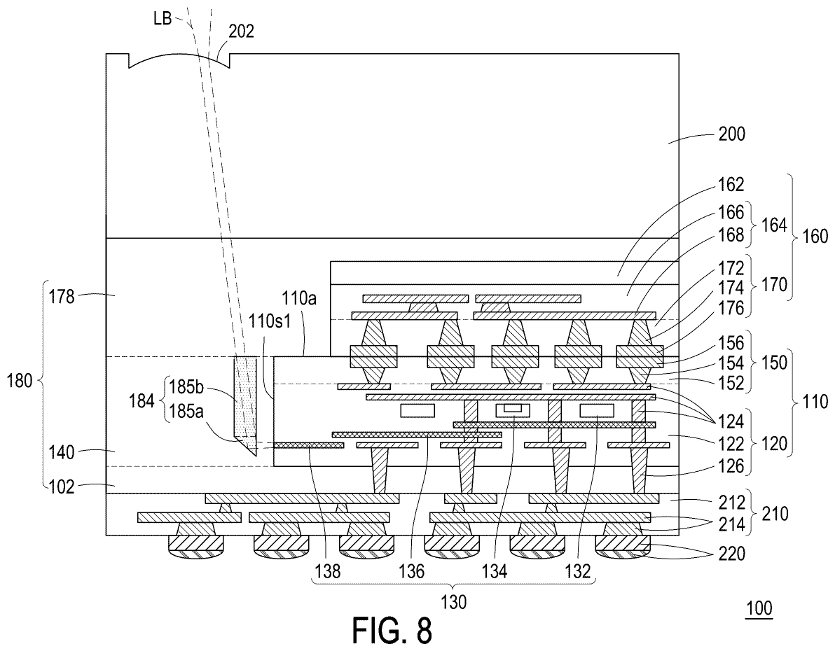

In some embodiments, the reflector coupler 184 is tilted with respect to the edge coupler 138 of the photonic die 110. However, the disclosure is not limited thereto. The reflector coupler 184 may be disposed at any desired angle. In alternative embodiments, as shown in FIG. 7, the reflector coupler 184 is not tilted with respect to the edge coupler 138 of the photonic die 110. In such embodiments, a surface 184a of the reflector coupler 184 is substantially coplanar with the surface (e.g., top surface) 140a of the dielectric layer 140. In alternative embodiments, as shown in FIG. 8, the reflector coupler 184 includes a prism-shaped portion 185a and an elongated portion 185b. The prism-shaped portion 185a is disposed corresponding to the edge coupler 138 of the photonic die 110, for example. The elongated portion 185b is connected to the prism-shaped portion 185a and extended along the sidewall 110s1 of the photonic die 110, for example. In such embodiments, a surface (e.g., facing the optical lens 202) 184a of the reflector coupler 184 is substantially coplanar with the surface 110a of the photonic die 110. For example, a surface 184a of the elongated portion 185b is substantially coplanar with the surface 110a of the photonic die 110.

In the above embodiments, the reflector coupler 184 is separated from the photonic die 110. However, the disclosure is not limited thereto.

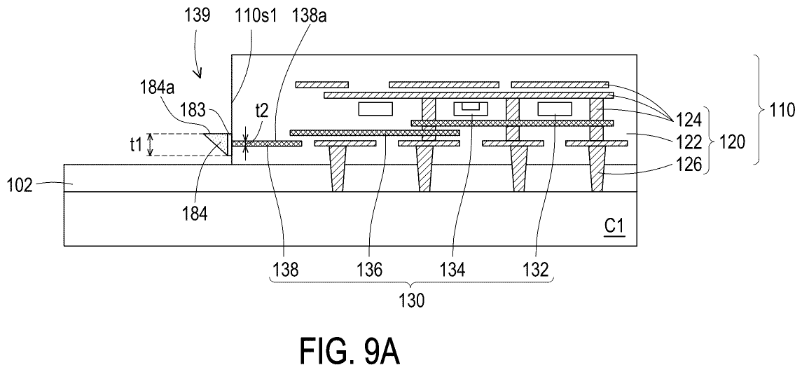

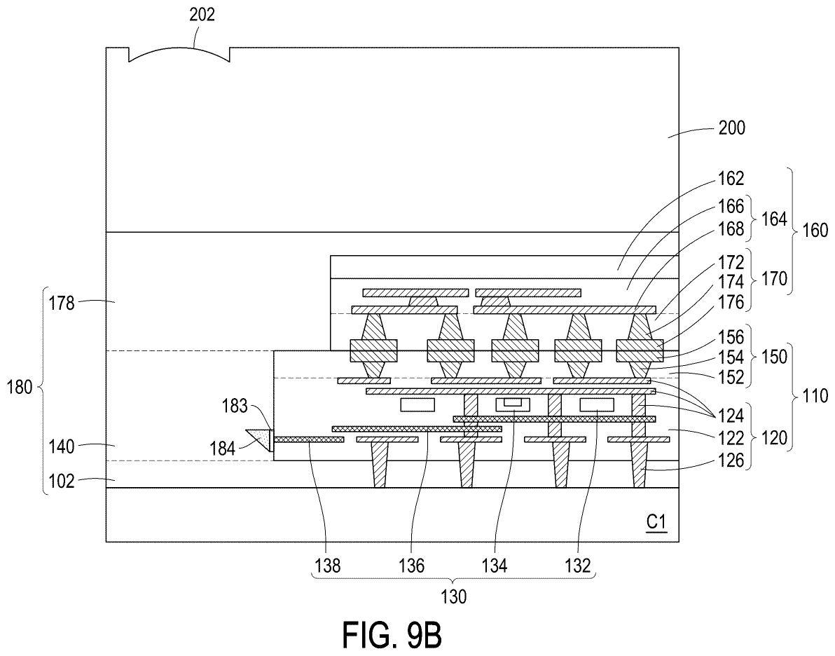

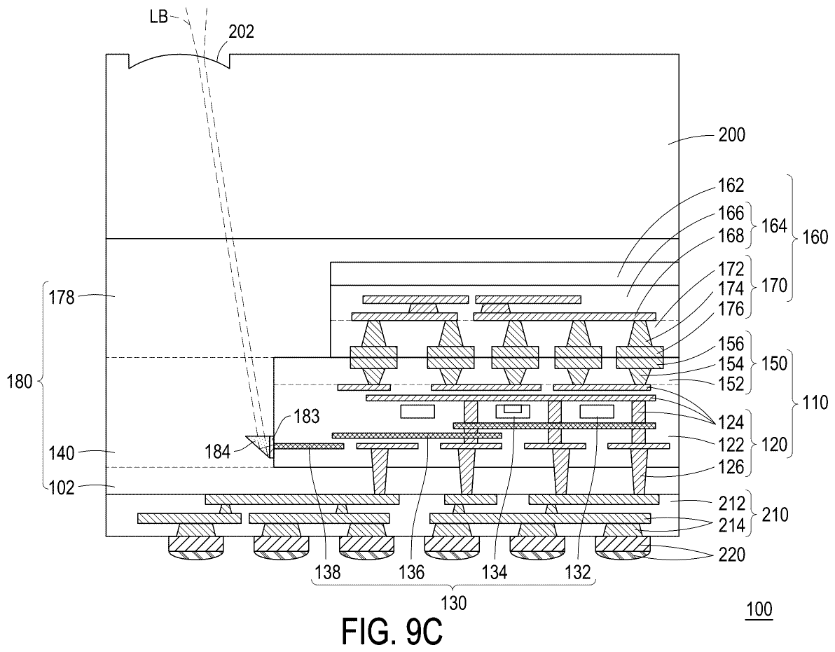

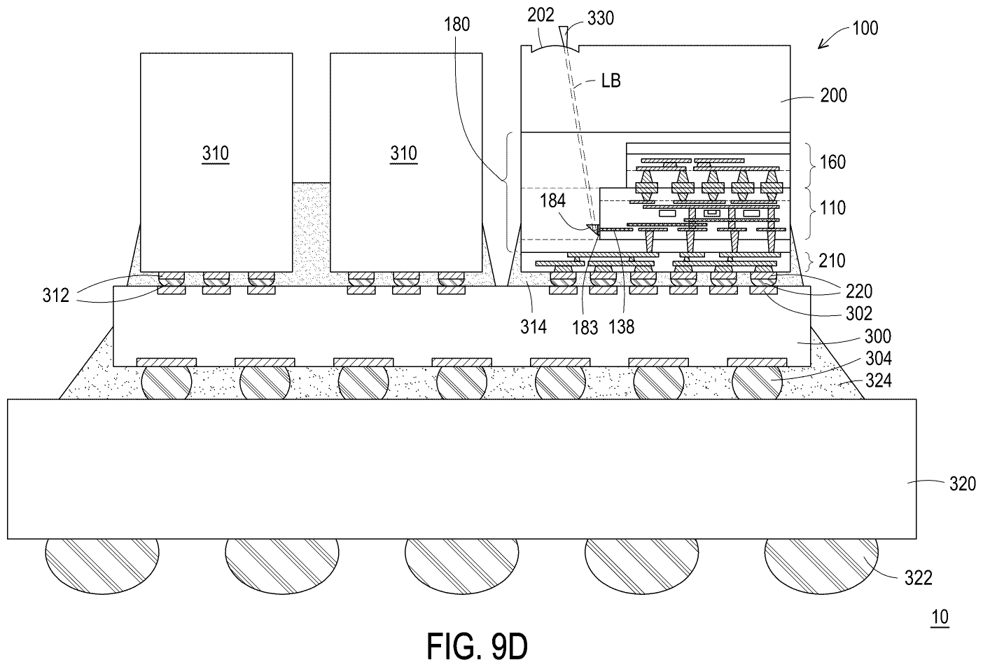

FIG. 9A to FIG. 9D are schematic cross-sectional views of various stages in a method of forming a semiconductor device according to some embodiments. The semiconductor device of FIG. 9D is similar to that of FIG. 1L, and the difference lies in that the configuration of the reflector coupler.

Referring to FIG. 9A, a dielectric layer 102 is formed over a carrier substrate C1, and a photonic die 110 is formed on the dielectric layer 102. The material and formation method of the dielectric layer 102 and the photonic die 110 are the same as or similar to those of the dielectric layer 102 and the photonic die 110 with reference to FIG. 1A and FIG. 1B, so the detailed description thereof is omitted herein.

Then, a reflector coupler 184 is formed on a sidewall 110s1 of the photonic die 110. For example, the reflector coupler 184 is attached to the sidewall 110s1 of the photonic die 110 through an adhesive 183 such as an optical glue. The adhesive 183 may include a polymer material and have a refractive index between about 1 and about 3. In some embodiments, the reflector coupler 184 is extended along the sidewall 110s1 of the photonic die 110 to cover the edge coupler 138 entirely. For example, a total thickness t1 of the reflector coupler 184 along the sidewall 110s1 is substantially equal to or larger than a total thickness t2 of the edge coupler 138. A surface 184a (e.g., top surface) of the reflector coupler 184 may be substantially flat or inclined. For example, as shown in FIG. 9A, the surface 184a (e.g., top surface) of the reflector coupler 184 is substantially flat, and thus the surface 184a (e.g., top surface) of the reflector coupler 184 is not tilted with respect to the edge coupler 138. For example, the surface 184a (e.g., top surface) of the reflector coupler 184 is substantially parallel to the surface 138a (e.g., top surface) of the edge coupler 138. However, the disclosure is not limited thereto. The reflector coupler 184 may be also tilted with respect to the edge coupler 138. In some embodiments in which the reflector coupler 184 is adhered to the photonic die 110, there is no need to form an opening/opening for the reflector coupler 184.

Referring to FIG. 9B, an electronic die 160 is bonded to the photonic die 110, and an encapsulant 180 is formed to encapsulant the reflector coupler 184, the photonic die 110 and the electronic die 160. For example, a dielectric layer 140 is formed to encapsulate the photonic die 110. Then, a bonding structure 150 is formed in the photonic die 110, and then the electronic die 160 is bonded to the photonic die 110 through bonding structures 150 and 170. After that, a dielectric layer 178 is formed to encapsulate the electronic die 160, and a support die 200 is bonded to the dielectric layer 178. In some embodiments, the encapsulant 180 includes the dielectric layers 102, 140, 178. The material, structure and formation method of the electronic die 160, the dielectric layers 140, 178 and the support die 200 are the same as or similar to those of the electronic die 160, the dielectric layers 140, 178 and the support die 200 described before, so the detailed description thereof is omitted herein.

Referring to FIG. 9C, a RDL structure 210 and conductive connectors 220 are formed, to form a package component 100. The structure and formation method of the RDL structure 210 and the conductive connectors 220 are the same as or similar to those of the RDL structure 210 and the conductive connectors 220 described above, so the detailed description thereof is omitted herein.

Referring to FIG. 9D, the package component 100 is bonded to an interconnect substrate 300 along with package components 310. Then, an underfill 314 is formed between the interconnect substrate 300 and the package components 100, 310. An optical fiber 330 may be attached to optical lens 202. The configuration and formation of the package components 310, underfill 314 and the optical fiber 330 are the same as or similar to those of the package components 310, underfill 314 and the optical fiber 330 described above, so the detailed description thereof is omitted herein.

The reflector coupler 184 is used for reflecting light. For example, as shown in FIG. 9C and FIG. 9D, when a light beam LB is projected from the optical fiber 330 (FIG. 9D) onto the reflector coupler 184, the light beam LB is reflected, and is projected on the edge couplers 138 as optical signals. The optical signals are transported through the optical waveguides 132 in the photonic die 110. The light beam LB may be reflected by the reflector coupler 184 back to the optical fiber 330 again, and redirected. That is, the direction (i.e., beam direction) of the light beam LB from the edge couplers 138 is turned by the reflector coupler 184, or the light beam LB is turned by the reflector coupler 184 and then incident into the edge couplers 138.

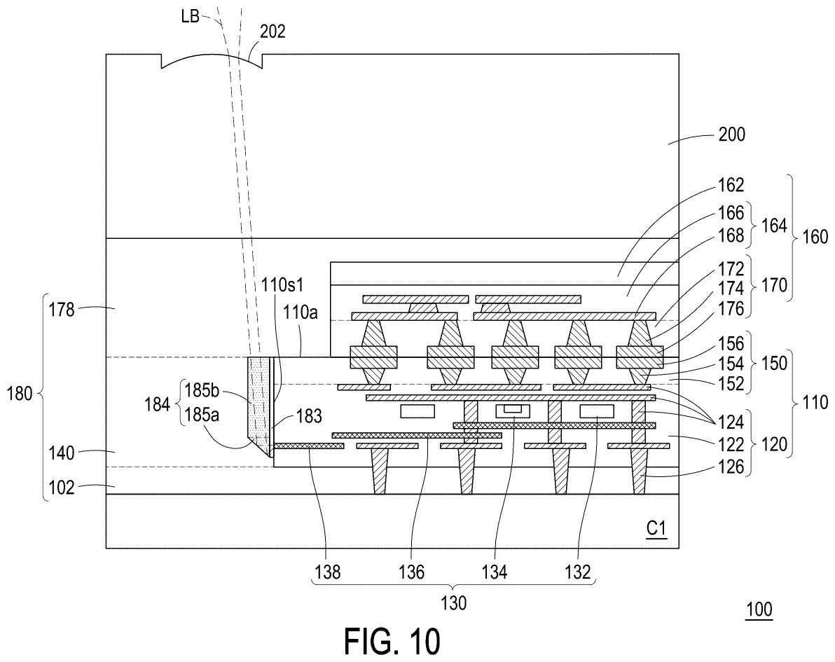

In some embodiments, the reflector coupler 184 disposed outside and attached to the photonic die 110 is prism-shaped. However, the disclosure is not limited thereto. In alternative embodiments, as shown in FIG. 10, the reflector coupler 184 disposed outside and attached to the photonic die 110 may have a configuration similar to that of FIG. 8. The reflector coupler 184 may have any suitable shape and/or size.

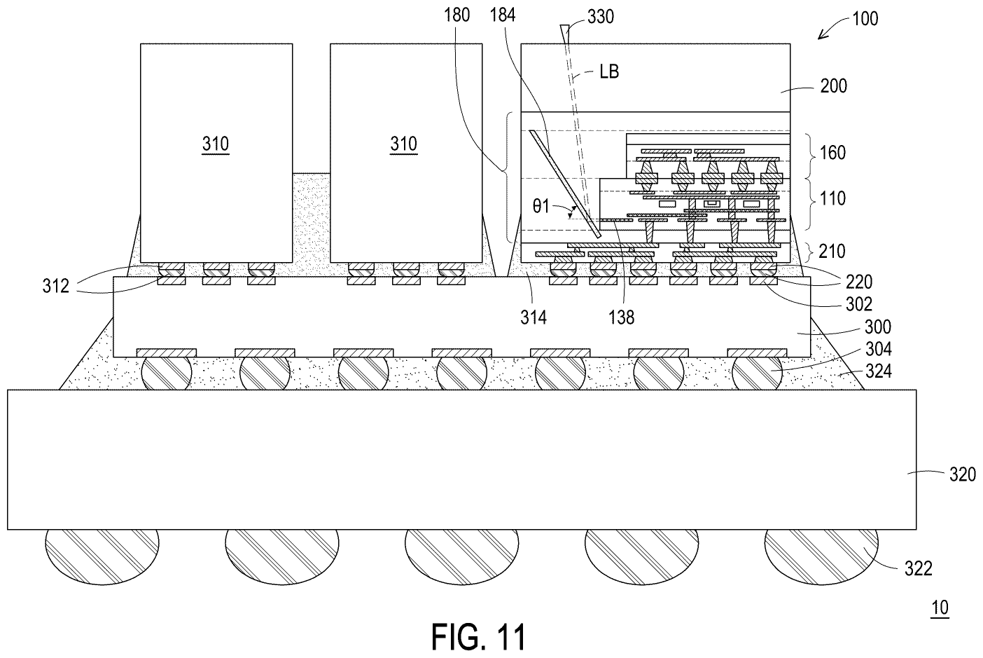

In the above embodiments, the optical fiber 330 is, for example, attached to the optical lens 202. However, the disclosure is not limited thereto. In alternative embodiments, as shown in FIG. 11, the optical lens 202 may be omitted, and the optical fiber 330 is directly connected to the support die 200. In such embodiments, the light beam LB may be directly projected from the optical fiber 330 onto the reflector coupler 184 and reflected, and the light beam LB from the photonic die 110 may be reflected by the reflector coupler 184 and directly back to the optical fiber 330.

In the above embodiments, since the reflector coupler 184 has an operating bandwidth larger than other coupler such as the grating coupler, the reflector coupler 184 may improve the operating bandwidth and may also improve coupling efficiency. For example, the reflector coupler 184 allows some technologies to improve the transmission capacities, for example, wavelength division mixing (WDM) technology, mode-division multiplexing (MDM) technology or the like, to be applied in COUPE, photonic engine system, or the like. Furthermore, the reflector coupler 184 is tilted disposed outside the photonic die 110 and in the package component 100 of the package 10 such as COUPE. Thus, the placement of the reflector coupler 184 is not limited by the dimension of the photonic die 110. Accordingly, the placement of the reflector coupler 184 may be achieved by any suitable method and have more design feasibilities. In addition, the reflector coupler may be further applied in any structure that requires coupling lights between optical fibers (e.g., vertical fibers) and optical couplers (e.g., waveguides) of the photonic die. For example, the reflector coupler is applied in Co-Package Optics, transceiver, photonic circuit, or the like.

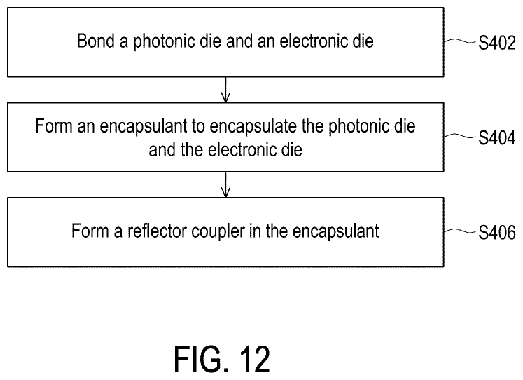

FIG. 12 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S402, a photonic die and an electronic die are bonded. FIGS. 1D, 2, 3A-3B, 4A-4B, 5A, 6B-6C, 7, 8, 9A-9B, 10 and 11 illustrate views corresponding to some embodiments of act S402.

At act S404, an encapsulant is formed to encapsulate the photonic die and the electronic die. FIGS. 1E, 2, 3A-3B, 4A-4B, 5A, 6B-6C, 7, 8, 9A-9B, 10 and 11 illustrate views corresponding to some embodiments of act S404.

At act S406, a reflector coupler is formed in the encapsulant. FIGS. 1F-1I, 2, 3A-3B, 4A-4B, 5C, 6B-6C, 7, 8, 9A-9B, 10 and 11 illustrate views corresponding to some embodiments of act S406.

According to some embodiments, a semiconductor device includes a photonic die and a reflector coupler. The photonic die includes an edge coupler. At least a portion of the reflector coupler is disposed outside the photonic die. A light from the edge coupler is reflected by the reflector coupler, or a light is reflected by the reflector coupler and then incident into the edge coupler.

According to some embodiments, a semiconductor device includes a photonic die, an electronic die and an encapsulant. The electronic die is bonded to the photonic die. The encapsulant encapsulates the electronic die and the photonic die.

According to some embodiments, a method of forming a semiconductor device includes following steps. A photonic die and an electronic die are bonded. An encapsulant is formed to encapsulate the photonic die and the electronic die. A reflector coupler is formed in the encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a photonic die, comprising an edge coupler; and
a reflector coupler, wherein at least a portion of the reflector coupler is disposed outside the photonic die, and a light from the edge coupler is reflected by the reflector coupler or a light is reflected by the reflector coupler and then incident into the edge coupler.

2. The semiconductor device of claim 1, wherein the reflector coupler is entirely disposed outside the photonic die.

3. The semiconductor device of claim 1, wherein the reflector coupler is partially disposed outside the photonic die and partially disposed in the photonic die.

4. The semiconductor device of claim 1, wherein the reflector coupler is further extended under the edge coupler.

5. The semiconductor device of claim 1, wherein the edge coupler is disposed at a sidewall of the photonic die, and the reflector coupler is tilted with respect to the sidewall of the photonic die.

6. The semiconductor device of claim 1, wherein the reflector coupler is a waveguide.

7. The semiconductor device of claim 1, further comprising a support die and an electronic die electrically connected to the photonic die, wherein the support die covers the electronic die and the photonic die and comprises an optical lens.

8. The semiconductor device of claim 7, wherein the support die further comprises an optical fiber, and the optical fiber is attached to the optical lens.

9. The semiconductor device of claim 1, further comprising a RDL structure and an electronic die electrically connected to the photonic die, wherein the photonic die is disposed between the electronic die and the RDL structure, and the reflector coupler further extends into an insulating layer of the RDL structure.

10. A semiconductor device, comprising:
a photonic die;
an electronic die, bonded to the photonic die; and
an encapsulant, wherein the encapsulant encapsulates the electronic die and the photonic die.

11. The semiconductor device of claim 10, wherein the photonic die comprises an edge coupler at a sidewall of the photonic die.

12. The semiconductor device of claim 11, further comprising a reflector coupler, wherein the reflector coupler comprises a reflecting surface facing the edge coupler and is tilted with respect to the edge coupler, and the encapsulant further encapsulates the reflector coupler.

13. The semiconductor device of claim 12, wherein the reflector coupler has a mirror shape or a prism-like shape.

14. The semiconductor device of claim 12, wherein the reflecting surface is planar or curved.

15. The semiconductor device of claim 12, wherein the reflector coupler is attached to the sidewall of the photonic die.

16. The semiconductor device of claim 12, wherein the encapsulant includes a light-transparent material having a reflective index smaller than the reflector coupler.

17. The semiconductor device of claim 12, wherein the encapsulant comprises:
a first dielectric layer, encapsulating the photonic die; and
a second dielectric layer, encapsulating the electronic die, wherein the reflector coupler extends from a surface of the second dielectric layer into the first dielectric layer.

18. The semiconductor device of claim 17, wherein the encapsulant further comprises a third dielectric layer, the third dielectric layer and the second dielectric layer are disposed at opposite sides of the first dielectric layer, and the reflector coupler further extends into the third dielectric layer.

19. A method of forming a semiconductor device, comprising:
bonding a photonic die and an electronic die;
forming an encapsulant to encapsulate the photonic die and the electronic die; and
forming a reflector coupler in the encapsulant.

20. The method of claim 19, wherein forming the reflector coupler comprises:
forming an opening in the encapsulant by an etching process; and
forming the reflector coupler in the opening.
